(19) United States
(12) Patent Application Publication
(10) Pub. No.: US 2026/0205114 A1
(43) Pub. Date: Jul. 16, 2026

(54) INSULATED SWITCH AND ELECTRONIC DEVICE

(71) Applicant: ROHM CO., LTD., Kyoto (JP)

(72) Inventor: Koji SAITO, Kyoto (JP)

(21) Appl. No.: 19/444,746

(22) Filed: Jan. 9, 2026

(30) Foreign Application Priority Data
Jan. 16, 2025 (JP) 2025-006187

(51) Int. Cl. H03K 17/689; H03K 17/74

(52) U.S. Cl. CPC H03K 17/689; H03K 17/74

(57) ABSTRACT

An insulated switch includes: a switch circuit connected between a first node and a second node and configured to be turned on and off by a switch drive signal; a pulse generation circuit configured to generate a first drive pulse and a second drive pulse in different phases; a switch drive circuit configured to receive a third drive pulse and a fourth drive pulse to generate the switch drive signal; and a first insulation capacitor and a second insulation capacitor configured to transmit the first drive pulse and the second drive pulse as the third drive pulse and the fourth drive pulse, respectively, while insulating the pulse generation circuit and the switch drive circuit from each other.

### CROSS REFERENCE TO RELATED APPLICATION

The present invention claims priority under 35 U.S.C. § 119 to Japanese Patent Application No. 2025-006187, filed on Jan. 16, 2025, the entire contents of which are incorporated herein by reference.

### TECHNICAL FIELD

The present disclosure relates to an insulated switch and an electronic device.

### BACKGROUND

In the related art, an insulated switch, which is configured to electrically insulate a primary-side circuit system and a secondary circuit system from each other and to drive a switch element of the secondary circuit system in response to a control signal from the primary-side circuit system, has been used in a variety of applications (such as a power supply device, a motor drive device, and the like).

In addition, one of techniques in the related art has been known by the discloser.

### BRIEF DESCRIPTION OF DRAWINGS

The accompanying drawings, which are incorporated in and constitute a part of the specification, illustrate embodiments of the present disclosure.

FIG. 1 is a diagram showing a basic configuration of a signal transmission device.

FIG. 2 is a diagram showing a basic structure of a transformer chip.

FIG. 3 is a perspective view of a semiconductor device used as a two-channel type transformer chip.

FIG. 4 is a plan view of the semiconductor device shown in FIG. 3.

FIG. 5 is a plan view showing a layer in which a low-potential coil is formed in the semiconductor device of FIG. 3.

FIG. 6 is a plan view showing a layer in which a high-potential coil is formed in the semiconductor device of FIG. 3.

FIG. 7 is a cross-sectional view taken along line VIII-VIII in FIG. 6.

FIG. 8 is an enlarged view (an isolated structure) of a region XIII shown in FIG. 7.

FIG. 9 is a schematic diagram showing a layout example of a transformer chip.

FIG. 10 is a diagram showing a comparative example of an insulated switch.

FIG. 11 is a diagram showing a first embodiment of an insulated switch.

FIG. 12 is a diagram showing a second embodiment of an insulated switch.

FIG. 13 is a diagram showing a third embodiment of an insulated switch.

FIG. 14 is a diagram showing a first example of a discharge circuit.

FIG. 15 is a diagram showing a second example of the discharge circuit.

FIG. 16 is a diagram showing a fourth embodiment of the insulated switch.

FIG. 17 is a diagram showing one configuration example of a voltage-controlled circuit.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Signal Transmission Device (Basic Configuration)

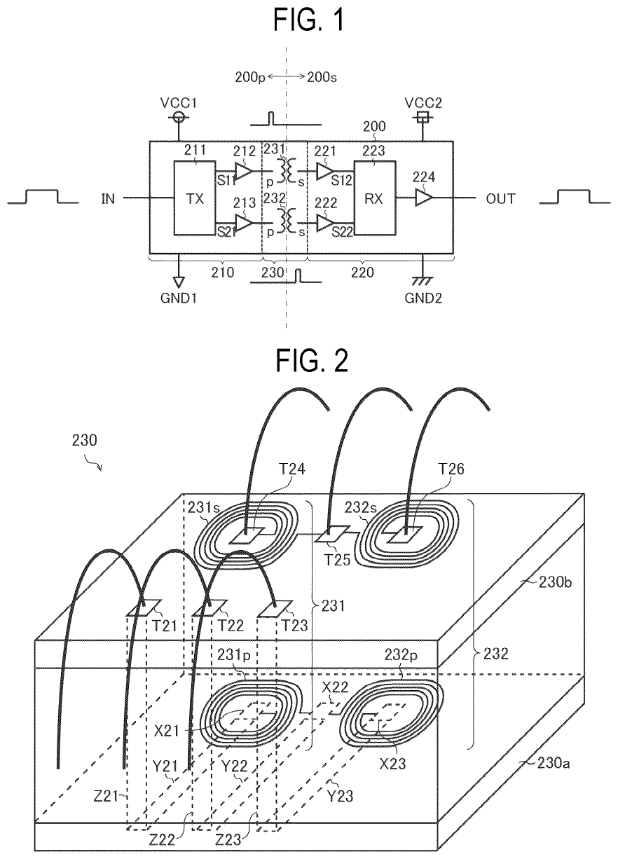

FIG. 1 is a diagram showing a basic configuration of a signal transmission device. A signal transmission device 200 of this configuration example is a semiconductor integrated circuit device (so-called insulated gate driver IC) that transmits pulse signals from a primary-side circuit system 200p (VCC1-GND1 system) to a secondary circuit system 200s (VCC2-GND2 system) while insulating the primary-side circuit system 200p from the secondary circuit system 200s, and drives a gate of a switch element (not shown) provided in the secondary circuit system 200s. For example, the signal transmission device 200 is implemented by sealing a controller chip 210, a driver chip 220, and a transformer chip 230 in a single package.

The controller chip 210 is a semiconductor chip that operates by being supplied with a power supply voltage VCC1 (for example, a maximum of 7 V with reference to GND1). For example, a pulse transmission circuit 211 and buffers 212 and 213 are integrated in the controller chip 210.

The pulse transmission circuit 211 is a pulse generator that generates transmission pulse signals S11 and S21 in response to an input pulse signal IN. More specifically, when the input pulse signal IN is at a high level, the pulse transmission circuit 211 drives the transmission pulse signal S11 (outputs a single shot of transmission pulse or a plural number of shots of transmission pulses) in a pulse manner. When the input pulse signal IN is at a low level, the pulse transmission circuit 211 drives the transmission pulse signal S21 in a pulse manner. That is, the pulse transmission circuit 211 drives either the transmission pulse signal S11 or S21 in a pulse manner in response to a logic level of the input pulse signal IN.

The buffer 212 receives the transmission pulse signal S11 from the pulse transmission circuit 211 and drives the transformer chip 230 (specifically, the transformer 231) in a pulse manner.

The buffer 213 receives the transmission pulse signal S21 from the pulse transmission circuit 211 and drives the transformer chip 230 (specifically, the transformer 232) in a pulse manner.

The driver chip 220 is a semiconductor chip that operates by being supplied with a power supply voltage VCC2 (for example, a maximum of 30 V with reference to GND2). For example, buffers 221 and 222, a pulse receiving circuit 223, and a driver 224 are integrated in the driver chip 220.

The buffer 221 shapes a waveform of the reception pulse signal S12 induced to the transformer chip 230 (specifically, the transformer 231) and outputs the same to the pulse receiving circuit 223.

The buffer 222 shapes a waveform of the reception pulse signal S22 induced to the transformer chip 230 (specifically, the transformer 232) and outputs the same to the pulse receiving circuit 223.

The pulse receiving circuit 223 generates an output pulse signal OUT by driving the driver 224 in response to the reception pulse signals S12 and S22 input via the buffers 221 and 222. More specifically, the pulse receiving circuit 223 drives the driver 224 so that the output pulse signal OUT rises to a high level in response to the pulse drive of the reception pulse signal S12, and the output pulse signal OUT falls to a low level in response to the pulse drive of the reception pulse signal S22. In other words, the pulse receiving circuit 223 switches a logic level of the output pulse signal OUT in response to a logic level of the input pulse signal IN. For example, an RS flip-flop may be suitably used as the pulse receiving circuit 223.

The driver 224 generates the output pulse signal OUT based on the drive control of the pulse receiving circuit 223.

While galvanically insulating the controller chip 210 and the driver chip 220 from each other using the transformers 231 and 232, the transformer chip 230 outputs the transmission pulse signals S11 and S21 input from the pulse transmission circuit 211 as reception pulse signals S12 and S22, respectively, to the pulse reception circuit 223. In this specification, the expression “galvanically insulating” means that objects to be insulated are not connected to each other by a conductor.

More specifically, the transformer 231 outputs the reception pulse signal S12 from the secondary-side coil 231s in response to the transmission pulse signal S11 input to the primary-side coil 231p. On the other hand, the transformer 232 outputs the reception pulse signal S22 from the secondary-side coil 232s in response to the transmission pulse signal S21 input to the primary-side coil 232p.

In this manner, due to characteristics of spiral coils used for insulation communication, the input pulse signal IN is separated into two transmission pulse signals S11 and S21 (which correspond to a rising signal and a falling signal), and then transmitted from the primary-side circuit system 200p to the secondary circuit system 200s via two transformers 231 and 232.

The signal transmission device 200 of this configuration example has an independent transformer chip 230 equipped with only the transformers 231 and 232, in addition to the controller chip 210 and the driver chip 220. These three chips are sealed in a single package.

With this configuration, both the controller chip 210 and the driver chip 220 may be formed thorough a general low-withstand to intermediate-withstand voltage process (withstand voltage of several volts to several tens of volts). This eliminates a need to use a dedicated high-withstand voltage process (withstand voltage of several kV), which makes it possible to reduce manufacturing costs.

The signal transmission device 200 may be suitably used, for example, in a power supply device or a motor drive device for a vehicle-borne equipment mounted in a vehicle. Examples of the vehicle may include not only an engine vehicle but also x electric vehicle (EV) such as a battery electric vehicle (BEV), a hybrid electric vehicle (HEV), a plug-in hybrid electric vehicle/plug-in hybrid vehicle (PHEV/PHV), or a fuel cell electric vehicle/fuel cell vehicle (FCEV/FCV).

### Transformer Chip (Basic Structure)

Next, a basic structure of the transformer chip 230 will be described. FIG. 2 shows the basic structure of the transformer chip 230. In the transformer chip 230 shown in this figure, the transformer 231 includes a primary-side coil 231p and a secondary-side coil 231s which face each other in an up-down direction. The transformer 232 includes a primary-side coil 232p and a secondary-side coil 232s which face each other in the up-down direction.

Both the primary-side coils 231p and 232p are formed in a first wiring layer (the lower layer) 230a of the transformer chip 230. Both the secondary-side coils 231s and 232s are formed in a second wiring layer (upper layer in this figure) 230b of the transformer chip 230. The secondary-side coil 231s is arranged directly above the primary-side coil 231p to face the primary-side coil 231p. The secondary-side coil 232s is arranged directly above the primary-side coil 232p to face the primary-side coil 232p.

The primary-side coil 231p is arranged in a spiral shape so as to surround a periphery of an internal terminal X21 in a clockwise direction using a first terminal connected to the internal terminal X21 as a start point. The primary-side coil 231p has a second terminal corresponding to its end point and connected to an internal terminal X22. On the other hand, the primary-side coil 232p is arranged in a spiral shape so as to surround a periphery of an internal terminal X23 in a counterclockwise direction using a first terminal connected to the internal terminal X23 as a start point. The primary-side coil 232p has a second terminal corresponding to its end point and connected to the internal terminal X22. The internal terminals X21, X22, and X23 are linearly arranged in the named order.

The internal terminal X21 is connected to an external terminal T21 in the second layer 230b via a conductive wiring Y21 and a via Z21. The internal terminal X22 is connected to an external terminal T22 in the second layer 230b via a conductive wiring Y22 and a via Z22. The internal terminal X23 is connected to an external terminal T23 in the second layer 230b via a conductive wiring Y23 and a via Z23. The external terminals T21 to T23 are arranged linearly and are used for wire bonding to the controller chip 210.

The secondary-side coil 231s is arranged in a spiral shape so as to surround a periphery of an external terminal T24 in a counterclockwise direction using a first terminal connected to the external terminal T24 as a start point. The secondary-side coil 231s has a second terminal corresponding to its end point and connected to an external terminal T25. On the other hand, the secondary-side coil 232s is arranged in a spiral shape so as to surround a periphery of an external terminal T26 in a clockwise direction using a first terminal connected to the external terminal T26 as a start point. The secondary-side coil 232s has a second terminal corresponding to its end point and connected to the external terminal T25. The external terminals T24, T25 and T26 are arranged linearly in the named order and are used for wire bonding to the driver chip 220.

The secondary-side coils 231s and 232s are connected to the primary-side coils 231p and 232p in an AC manner by magnetic coupling, and are galvanically insulated from the primary-side coils 231p and 232p. That is, the driver chip 220 is connected to the controller chip 210 in the AC manner via the transformer chip 230, and is galvanically insulated from the controller chip 210 by the transformer chip 230.

### Transformer Chip (Two-Channel Type)

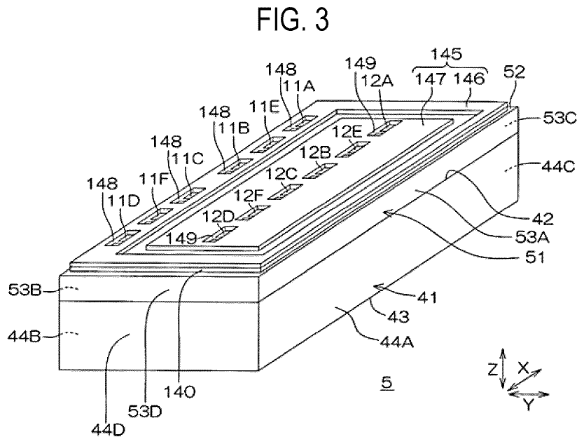

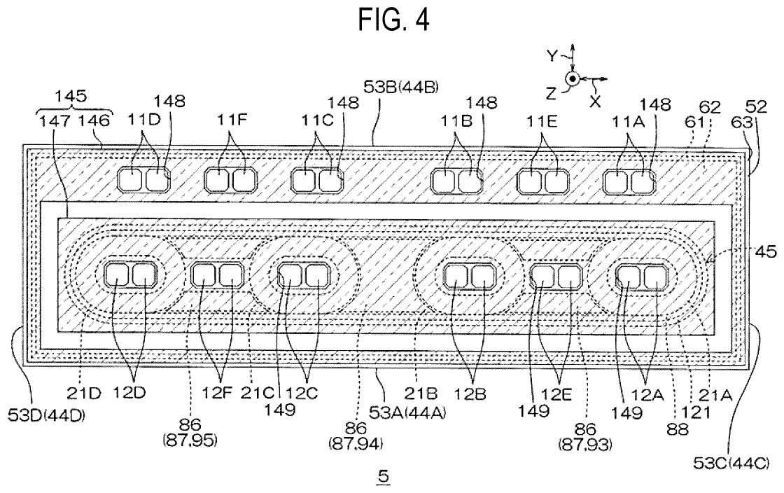

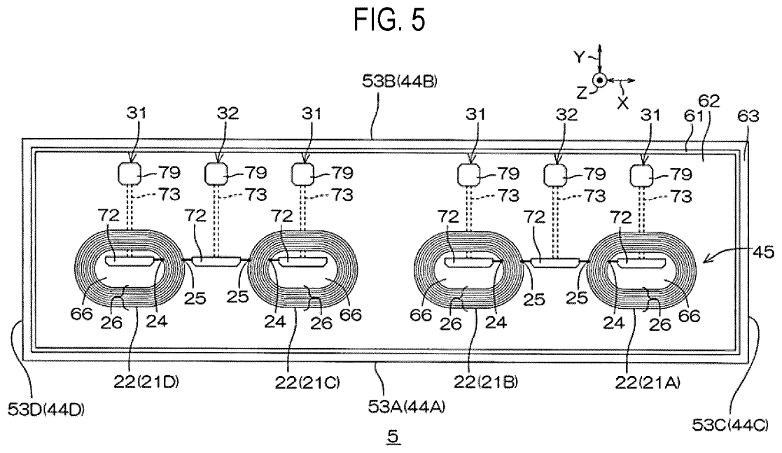

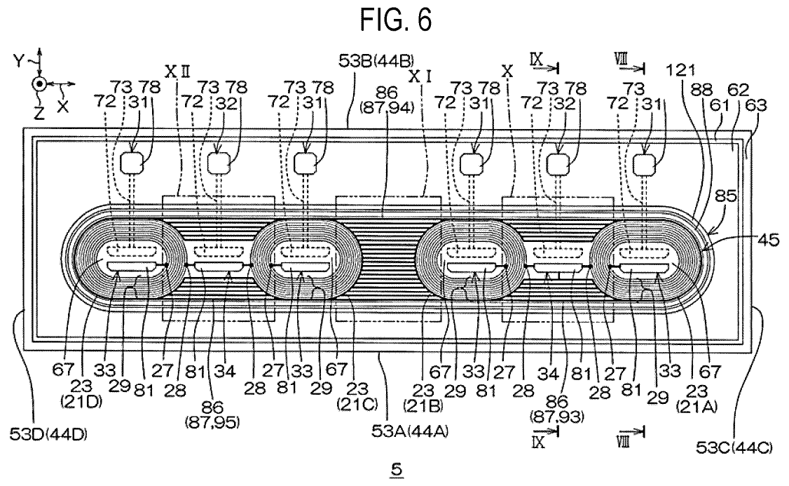

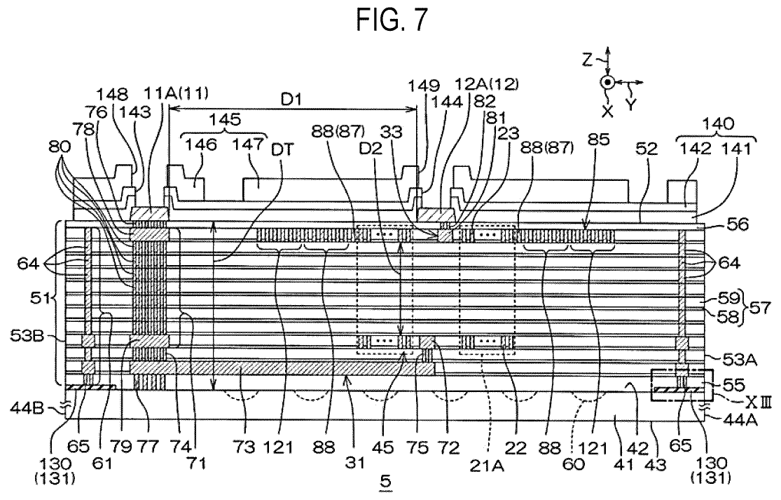

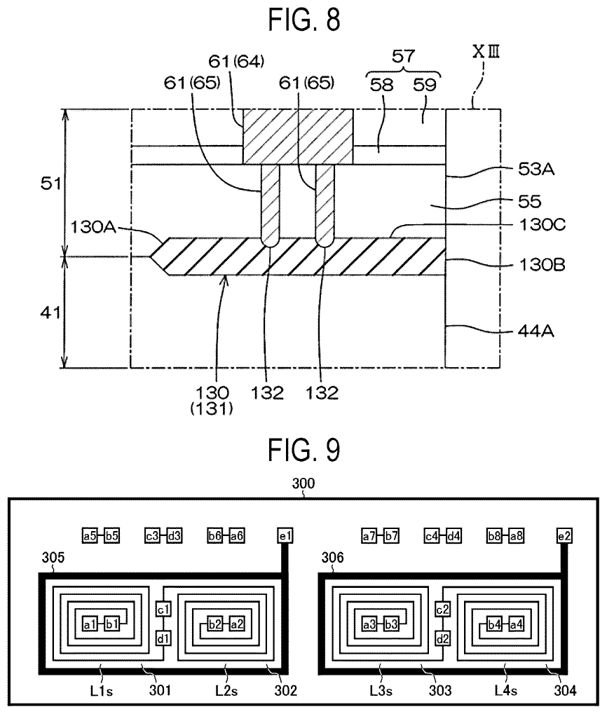

FIG. 3 is a perspective view showing a semiconductor device 5 used as a two-channel type transformer chip. FIG. 4 is a plan view of the semiconductor device 5 shown in FIG. 3. FIG. 5 is a plan view showing a layer in which a low-potential coil 22 (corresponding to the primary-side coil of the transformer) is formed in the semiconductor device 5 shown in FIG. 3. FIG. 6 is a plan view showing a layer in which a high-potential coil 23 (corresponding to the secondary-side coil of the transformer) is formed in the semiconductor device 5 shown in FIG. 3. FIG. 7 is a cross-sectional view taken along line VIII-VIII in FIG. 6. FIG. 8 is an enlarged view of region XIII in FIG. 7, showing an isolated structure 130.

Referring to FIGS. 3 to 7, the semiconductor device 5 includes a rectangular parallelepiped semiconductor chip 41. The semiconductor chip 41 includes at least one of silicon, a wide bandgap semiconductor, or a compound semiconductor.

The wide bandgap semiconductor is a semiconductor with a bandgap exceeding that of silicon (approximately 1.12 eV). The bandgap of the wide bandgap semiconductor is preferably 2.0 eV or more. The wide bandgap semiconductor may be SiC (silicon carbide). The compound semiconductor may be a III-V group compound semiconductor. The compound semiconductor may include at least one of AlN (aluminum nitride), InN (indium nitride), GaN (gallium nitride), or GaAs (gallium arsenide).

In this embodiment, the semiconductor chip 41 includes a silicon-made semiconductor substrate. The semiconductor chip 41 may be an epitaxial substrate having a stacked structure composed of a silicon-made semiconductor substrate and a silicon epitaxial layer. A conductivity type of the semiconductor substrate may be an n-type or a p-type. The epitaxial layer may be of an n-type or a p-type.

The semiconductor chip 41 has a first main surface 42 on one side, a second main surface 43 on the other side, and chip sidewalls 44A to 44D connecting the first main surface 42 and the second main surface 43. The first main surface 42 and the second main surface 43 are formed in a quadrangular shape (rectangular shape in this embodiment) in a plan view seen from their normal direction Z (hereinafter, simply referred to as “in a plan view”).

The chip sidewalls 44A to 44D include a first chip sidewall 44A, a second chip sidewall 44B, a third chip sidewall 44C, and a fourth chip sidewall 44D. The first chip sidewall 44A and the second chip sidewall 44B form long sides of the semiconductor chip 41. The first chip sidewall 44A and the second chip sidewall 44B extend along a first direction X and face each other in a second direction Y. The third chip sidewall 44C and the fourth chip sidewall 44D form short sides of the semiconductor chip 41. The third chip sidewall 44C and the fourth chip sidewall 44D extend in the second direction Y and face each other in the first direction X. The chip sidewalls 44A to 44D are composed of ground surfaces.

The semiconductor device 5 further includes an insulating layer 51 formed on the first main surface 42 of the semiconductor chip 41. The insulating layer 51 has an insulating main surface 52 and insulating sidewalls 53A to 53D. The insulating main surface 52 is formed in a quadrangular shape (rectangular shape in this embodiment) which coincides with the first main surface 42 in a plan view. The insulating main surface 52 extends parallel to the first main surface 42.

The insulating sidewalls 53A to 53D include a first insulating sidewall 53A, a second insulating sidewall 53B, a third insulating sidewall 53C, and a fourth insulating sidewall 53D. The insulating sidewalls 53A to 53D extend from a peripheral edge of the insulating main surface 52 toward the semiconductor chip 41 and are continuous with the chip sidewalls 44A to 44D. Specifically, the insulating sidewalls 53A to 53D are formed to be flush with the chip sidewalls 44A to 44D. The insulating sidewalls 53A to 53D form ground surfaces flush with the chip sidewalls 44A to 44D.

The insulating layer 51 has a multilayer insulating stacked structure including a lowermost insulating layer 55, an uppermost insulating layer 56, and a plurality of (eleven in this embodiment) interlayer insulating layers 57. The lowermost insulating layer 55 is an insulating layer that directly covers the first main surface 42. The uppermost insulating layer 56 is an insulating layer that forms the insulating main surface 52. The plurality of interlayer insulating layers 57 are insulating layers interposed between the lowermost insulating layer 55 and the uppermost insulating layer 56. In this embodiment, the lowermost insulating layer 55 has a single-layer structure including a silicon oxide. In this embodiment, the uppermost insulating layer 56 also has a single-layer structure including the silicon oxide. A thickness of each of the lowermost insulating layer 55 and the uppermost insulating layer 56 may be 1 μm or more and 3 μm or less (for example, approximately 2 μm).

Each of the plurality of interlayer insulating layers 57 has a stacked structure including a first insulating layer 58 on the side of the lowermost insulating layer 55 and a second insulating layer 59 on the side of the uppermost insulating layer 56. The first insulating layer 58 may include a silicon nitride. The first insulating layer 58 is formed as an etching stopper layer for the second insulating layer 59. A thickness of the first insulating layer 58 may be 0.1 μm or more and 1 μm or less (for example, approximately 0.3 μm).

The second insulating layer 59 is formed on the first insulating layer 58. The second insulating layer 59 contains an insulating material different from that of the first insulating layer 58. The second insulating layer 59 may contain silicon oxide. A thickness of the second insulating layer 59 may be 1 μm or more and 3 μm or less (for example, approximately 2 μm). The thickness of the second insulating layer 59 is preferably greater than the thickness of the first insulating layer 58.

A total thickness DT of the insulating layer 51 may be 5 μm or more and 50 μm or less. The total thickness DT of the insulating layer 51 and the number of stacked interlayer insulating layers 57 are optional and are adjusted according to a dielectric withstand voltage (dielectric breakdown resistance) to be implemented. Further, the insulating materials of the lowermost insulating layer 55, the uppermost insulating layer 56, and the interlayer insulating layers 57 are optional and are not limited to a specific insulating material.

The semiconductor device 5 includes a first functional device 45 formed in the insulating layer 51. The first functional device 45 includes one or more (a plurality of, in this embodiment) transformers 21 (corresponding to the aforementioned transformers). In other words, the semiconductor device 5 is a multi-channel type device including a plurality of transformers 21. The plurality of transformers 21 are formed inward of the insulating layer 51 so as to be spaced apart from the insulating sidewalls 53A to 53D. The plurality of transformers 21 are formed to be spaced apart in the first direction X.

Specifically, the plurality of transformers 21 include a first transformer 21A, a second transformer 21B, a third transformer 21C, and a fourth transformer 21D, which are formed in the named order from the side of the insulating sidewall 53C toward the insulating sidewall 53D in a plan view. The plurality of transformers 21A to 21D have a similar structure. In the following, a structure of the first transformer 21A will be described as an example. Structures of the second transformer 21B, the third transformer 21C, and the fourth transformer 21D are similar to the structure of the first transformer 21A, and therefore, descriptions thereof will be omitted.

Referring to FIGS. 5 to 7, the first transformer 21A includes a low-potential coil 22 and a high-potential coil 23. The low-potential coil 22 is formed in the insulating layer 51. The high-potential coil 23 is formed in the insulating layer 51 so as to face the low-potential coil 22 in a normal direction Z. In this embodiment, the low-potential coil 22 and the high-potential coil 23 are formed in a region sandwiched between the lowermost insulating layer 55 and the uppermost insulating layer 56 (that is, in the plurality of interlayer insulating layers 57).

The low-potential coil 22 is formed on the side of the lowermost insulating layer 55 (the semiconductor chip 41) inside the insulating layer 51, and the high-potential coil 23 is formed on the side of the uppermost insulating layer 56 (the insulating main surface 52) relative to the low-potential coil 22 inside the insulating layer 51. In other words, the high-potential coil 23 faces the semiconductor chip 41 with the low-potential coil 22 sandwiched therebetween. The low-potential coil 22 and the high-potential coil 23 may be arranged at any desired locations. Further, the high-potential coil 23 may face the low-potential coil 22 with one or more interlayer insulating layers 57 sandwiched therebetween.

A distance between the low-potential coil 22 and the high-potential coil 23 (that is, the number of the interlayer insulating layers 57 stacked one above another) is adjusted appropriately according to a dielectric strength voltage and an electric field intensity between the low-potential coil 22 and the high-potential coil 23. In this embodiment, the low-potential coil 22 is formed in the third interlayer insulating layer 57 counted from the lowermost insulating layer 55. In this embodiment, the high-potential coil 23 is formed in the first interlayer insulating layer 57 counted from the uppermost insulating layer 56.

The low-potential coil 22 is embedded in the interlayer insulating layers 57 so as to penetrate the first insulating layer 58 and the second insulating layer 59. The low-potential coil 22 includes a first inner end 24, a first outer end 25, and a first spiral portion 26 that is wound in a spiral shape between the first inner end 24 and the first outer end 25. The first spiral portion 26 is wound spirally so as to extend in an elliptical shape (oval shape) in a plan view. A portion that forms the innermost peripheral edge of the first spiral portion 26 defines a first inner region 66 that is elliptical in a plan view.

The number of turns of the first spiral portion 26 may be 5 or more and 30 or less. A width of the first spiral portion 26 may be 0.1 μm or more and 5 μm or less. The width of the first spiral portion 26 is preferably 1 μm or more and 3 μm or less. The width of the first spiral portion 26 is defined by the width in a direction perpendicular to the spiral direction. A first winding pitch of the first spiral portion 26 may be 0.1 μm or more and 5 μm or less. The first winding pitch is preferably 1 μm or more and 3 μm or less. The first winding pitch is defined by a distance between two adjacent portions of the first spiral portion 26 in a direction perpendicular to the spiral direction.

The winding shape of the first spiral portion 26 and the plan-view shape of the first inner region 66 are optional and are not limited to ones shown in FIG. 5 and the like. The first spiral portion 26 may be wound in a polygonal shape such as a triangular shape or a quadrangular shape, or in a circular shape in a plan view. The first inner region 66 may be partitioned into a polygonal shape such as a triangular shape or a quadrangular shape, or into a circular shape in a plan view, according to the winding shape of the first spiral portion 26.

The low-potential coil 22 may contain at least one of titanium, titanium nitride, copper, aluminum, or tungsten. The low-potential coil 22 may have a stacked structure composed of a barrier layer and a main body layer. The barrier layer defines a recess space in the interlayer insulating layers 57. The barrier layer may contain at least one of titanium or titanium nitride. The main body layer may contain at least one of copper, aluminum, or tungsten.

The high-potential coil 23 is embedded in the interlayer insulating layers 57 so as to penetrate the first insulating layer 58 and the second insulating layer 59. The high-potential coil 23 includes a second inner end 27, a second outer end 28, and a second spiral portion 29 wound in a spiral shape between the second inner end 27 and the second outer end 28. The second spiral portion 29 is wound spirally so as to extend in an elliptical (oval) shape in a plan view. In this embodiment, a portion forming the innermost peripheral edge of the second spiral portion 29 defines a second inner region 67 that is elliptical in a plan view. The second inner region 67 of the second spiral portion 29 faces the first inner region 66 of the first spiral portion 26 in the normal direction Z.

The number of turns of the second spiral portion 29 may be 5 or more and 30 or less. The number of turns of the second spiral portion 29 relative to the number of turns of the first spiral portion 26 is adjusted according to a voltage value to be boosted. The number of turns of the second spiral portion 29 may preferably exceed the number of turns of the first spiral portion 26. Of course, the number of turns of the second spiral portion 29 may be smaller than the number of turns of the first spiral portion 26 or may be equal to the number of turns of the first spiral portion 26.

A width of the second spiral portion 29 may be 0.1 μm or more and 5 μm or less. The width of the second spiral portion 29 is preferably 1 μm or more and 3 μm or less. The width of the second spiral portion 29 is defined by a width in a direction perpendicular to the spiral direction. The width of the second spiral portion 29 is preferably equal to the width of the first spiral portion 26.

A second winding pitch of the second spiral portion 29 may be 0.1 μm or more and 5 μm or less. The second winding pitch is preferably 1 μm or more and 3 μm or less. The second winding pitch is defined by a distance between two adjacent portions of the second spiral portion 29 in a direction perpendicular to the spiral direction. The second winding pitch is preferably equal to the first winding pitch of the first spiral portion 26.

The winding shape of the second spiral portion 29 and the plan-view shape of the second inner region 67 are optional and are not limited to ones shown in FIG. 6 and the like. The second spiral portion 29 may be wound in a polygonal shape such as a triangular shape or a quadrangular shape, or in a circular shape in a plan view. The second inner region 67 may be partitioned into a polygonal shape such as a triangular shape or a quadrangular shape, or in a circular shape in a plan view, according to the winding shape of the second spiral portion 29.

The high-potential coil 23 is preferably formed of the same conductive material as the low-potential coil 22. That is, like the low-potential coil 22, the high-potential coil 23 preferably includes a barrier layer and a main body layer.

Referring to FIG. 4, the semiconductor device 5 includes a plurality of (twelve in this figure) low-potential terminals 11 and a plurality of (twelve in this figure) high-potential terminals 12. The plurality of low-potential terminals 11 are electrically connected to the low-potential coils 22 of the corresponding transformers 21A to 21D. The plurality of high-potential terminals 12 are electrically connected to the high-potential coils 23 of the corresponding transformers 21A to 21D.

The plurality of low-potential terminals 11 are formed on the insulating main surface 52 of the insulating layer 51. Specifically, the plurality of low-potential terminals 11 are formed in a region on the side of the insulating sidewall 53B at intervals in the second direction Y from the plurality of transformers 21A to 21D, and are arranged at intervals in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. In this embodiment, two of each of the plurality of low potential terminals 11A to 11F are formed. The number of the plurality of low-potential terminals 11A to 11F is optional.

The first low-potential terminal 11A faces the first transformer 21A in the second direction Y in a plan view. The second low-potential terminal 11B faces the second transformer 21B in the second direction Y in a plan view. The third low-potential terminal 11C faces the third transformer 21C in the second direction Y in a plan view. The fourth low-potential terminal 11D faces the fourth transformer 21D in the second direction Y in a plan view. The fifth low-potential terminal 11E is formed in a region between the first low-potential terminal 11A and the second low-potential terminal 11B in a plan view. The sixth low-potential terminal 11F is formed in a region between the third low-potential terminal 11C and the fourth low-potential terminal 11D in a plan view.

The first low-potential terminal 11A is electrically connected to the first inner end 24 of the first transformer 21A (the low-potential coil 22). The second low-potential terminal 11B is electrically connected to the first inner end 24 of the second transformer 21B (the low-potential coil 22). The third low-potential terminal 11C is electrically connected to the first inner end 24 of the third transformer 21C (the low-potential coil 22). The fourth low-potential terminal 11D is electrically connected to the first inner end 24 of the fourth transformer 21D (the low-potential coil 22).

The fifth low-potential terminal 11E is electrically connected to the first outer end 25 of the first transformer 21A (the low-potential coil 22) and the first outer end 25 of the second transformer 21B (the low-potential coil 22). The sixth low-potential terminal 11F is electrically connected to the first outer end 25 of the third transformer 21C (the low-potential coil 22) and the first outer end 25 of the fourth transformer 21D (the low-potential coil 22).

The plurality of high-potential terminals 12 are formed on the insulating main surface 52 of the insulating layer 51 at intervals from the plurality of low-potential terminals 11. Specifically, the plurality of high-potential terminals 12 are formed in a region on the side of the insulating sidewall 53A at intervals from the plurality of low-potential terminals 11 in the second direction Y, and are arranged at intervals in the first direction X.

The plurality of high-potential terminals 12 are formed respectively in regions close to the corresponding transformers 21A to 21D in a plan view. The expression “the high-potential terminals 12 close to the transformers 21A to 21D” means that the distance between the high-potential terminals 12 and the transformers 21 in a plan view is less than the distance between the low-potential terminals 11 and the high-potential terminals 12.

Specifically, the plurality of high-potential terminals 12 are formed at intervals along the first direction X so as to face the plurality of transformers 21A to 21D along the first direction X in a plan view. More specifically, the plurality of high-potential terminals 12 are formed at intervals along the first direction X so as to be located in the second inner region 67 of the high-potential coil 23 and in the region between adjacent high-potential coils 23 in a plan view. As a result, the plurality of high-potential terminals 12 are arranged in a line with the plurality of transformers 21A to 21D in the first direction X in a plan view.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. In this embodiment, two of each of the plurality of high-potential terminals 12A to 12F are formed. The number of the plurality of high-potential terminals 12A to 12F may be optional.

The first high-potential terminal 12A is formed in the second inner region 67 of the first transformer 21A (the high-potential coil 23) in a plan view. The second high-potential terminal 12B is formed in the second inner region 67 of the second transformer 21B (the high-potential coil 23) in a plan view. The third high-potential terminal 12C is formed in the second inner region 67 of the third transformer 21C (the high-potential coil 23) in a plan view. The fourth high-potential terminal 12D is formed in the second inner region 67 of the fourth transformer 21D (the high-potential coil 23) in a plan view. The fifth high-potential terminal 12E is formed in a region between the first transformer 21A and the second transformer 21B in a plan view. The sixth high-potential terminal 12F is formed in a region between the third transformer 21C and the fourth transformer 21D in a plan view.

The first high-potential terminal 12A is electrically connected to the second inner end 27 of the first transformer 21A (the high-potential coil 23). The second high-potential terminal 12B is electrically connected to the second inner end 27 of the second transformer 21B (the high-potential coil 23). The third high-potential terminal 12C is electrically connected to the second inner end 27 of the third transformer 21C (the high-potential coil 23). The fourth high-potential terminal 12D is electrically connected to the second inner end 27 of the fourth transformer 21D (the high-potential coil 23).

The fifth high-potential terminal 12E is electrically connected to the second outer end 28 of the first transformer 21A (the high-potential coil 23) and the second outer end 28 of the second transformer 21B (the high-potential coil 23). The sixth high-potential terminal 12F is electrically connected to the second outer end 28 of the third transformer 21C (the high-potential coil 23) and the second outer end 28 of the fourth transformer 21D (the high-potential coil 23).

Referring to FIGS. 5 to 7, the semiconductor device 5 includes a first low-potential wiring 31, a second low-potential wiring 32, a first high-potential wiring 33, and a second high-potential wiring 34, each of which is formed in the insulating layer 51. In this embodiment, a plurality of the first low-potential wirings 31, a plurality of the second low-potential wirings 32, a plurality of the first high-potential wirings 33, and a plurality of the second high-potential wirings 34 are formed.

The first low-potential wiring 31 and the second low-potential wiring 32 fix the low-potential coil 22 of the first transformer 21A and the low-potential coil 22 of the second transformer 21B at the same potential. The first low-potential wiring 31 and the second low-potential wiring 32 also fix the low-potential coil 22 of the third transformer 21C and the low-potential coil 22 of the fourth transformer 21D at the same potential. In this embodiment, the first low-potential wiring 31 and the second low-potential wiring 32 fix all the low-potential coils 22 of the transformers 21A to 21D at the same potential.

The first high-potential wiring 33 and the second high-potential wiring 34 fix the high-potential coil 23 of the first transformer 21A and the high-potential coil 23 of the second transformer 21B at the same potential. The first high-potential wiring 33 and the second high-potential wiring 34 also fix the high-potential coil 23 of the third transformer 21C and the high-potential coil 23 of the fourth transformer 21D at the same potential. In this embodiment, the first high-potential wiring 33 and the second high-potential wiring 34 fix all the high-potential coils 23 of the transformers 21A to 21D at the same potential.

The plurality of first low-potential wirings 31 are electrically connected to the corresponding low-potential terminals 11A to 11D and the first inner ends 24 of the corresponding transformers 21A to 21D (the low-potential coils 22). The plurality of first low-potential wirings 31 have the same structure. In the following, a structure of the first low-potential wiring 31 connected to the first low-potential terminal 11A and the first transformer 21A will be described as an example. Structures of the other first low-potential wirings 31 are similar to the structure of the first low-potential wiring 31 connected to the first transformer 21A, and therefore, descriptions thereof will be omitted.

The first low-potential wiring 31 includes a penetration wiring 71, a low-potential connection wiring 72, a lead-out wiring 73, a first connection plug electrode 74, a second connection plug electrode 75, one or more (a plurality of, in this embodiment) pad plug electrodes 76, and one or more (a plurality of, in this embodiment) substrate plug electrodes 77.

The penetration wiring 71, the low-potential connection wiring 72, the lead wiring 73, the first connection plug electrode 74, the second connection plug electrode 75, the pad plug electrode 76, and the substrate plug electrode 77 are preferably formed of the same conductive material as the low-potential coil 22 or the like. In other words, each of the penetration wiring 71, the low-potential connection wiring 72, the lead wiring 73, the first connection plug electrode 74, the second connection plug electrode 75, the pad plug electrode 76, and the substrate plug electrode 77 preferably include a barrier layer and a main body layer, like the low-potential coil 22 and the like.

The penetration wiring 71 penetrates the plurality of interlayer insulating layers 57 in the insulating layer 51 and extends in a columnar shape along the normal direction Z. In this embodiment, the penetration wiring 71 is formed in a region of the insulating layer 51 between the lowermost insulating layer 55 and the uppermost insulating layer 56. The penetration wiring 71 has an upper end portion on the side of the uppermost insulating layer 56 and a lower end portion on the side of the lowermost insulating layer 55. The upper end portion of the penetration wiring 71 is formed in the same interlayer insulating layer 57 as the high-potential coil 23 and is covered by the uppermost insulating layer 56. The lower end portion of the penetration wiring 71 is formed in the same interlayer insulating layer 57 as the low-potential coil 22.

In this embodiment, the penetration wiring 71 includes a first electrode layer 78, a second electrode layer 79, and a plurality of wiring plug electrodes 80. In the penetration wiring 71, each of the first electrode layer 78, the second electrode layer 79, and the wiring plug electrodes 80 is formed of the same conductive material as the low-potential coil 22 or the like. In other words, each of the first electrode layer 78, the second electrode layer 79, and the wiring plug electrodes 80 includes a barrier layer and a main body layer, like the low-potential coil 22 and the like.

The first electrode layer 78 forms the upper end portion of the penetration wiring 71. The second electrode layer 79 forms the lower end portion of the penetration wiring 71. The first electrode layer 78 is formed in an island shape to face the low-potential terminal 11 (the first low-potential terminal 11A) in the normal direction Z. The second electrode layer 79 is formed in an island shape to face the first electrode layer 78 in the normal direction Z.

The plurality of wiring plug electrodes 80 are embedded respectively in the plurality of interlayer insulating layers 57 located in the region between the first electrode layer 78 and the second electrode layer 79. The plurality of wiring plug electrodes 80 are stacked from the lowermost insulating layer 55 toward the uppermost insulating layer 56 so as to be electrically connected to one another, and are configured to electrically connect the first electrode layer 78 and the second electrode layer 79. Each of the plurality of wiring plug electrodes 80 has a plan-view area that is smaller than those of the first electrode layer 78 and the second electrode layer 79.

The number of wiring plug electrodes 80 stacked one above another is equal to the number of interlayer insulating layers 57 stacked one above another. In this embodiment, six wiring plug electrodes 80 are embedded in each interlayer insulating layer 57, but the number of wiring plug electrodes 80 embedded in each interlayer insulating layer 57 is optional. Of course, one or more wiring plug electrodes 80 may be formed to penetrate the plurality of interlayer insulating layers 57.

The low-potential connection wiring 72 is formed in the first inner region 66 of the first transformer 21A (the low-potential coil 22) in the same interlayer insulating layer 57 as the low-potential coil 22. The low-potential connection wiring 72 is formed in an island shape to face the high-potential terminal 12 (the first high-potential terminal 12A) in the normal direction Z. The low-potential connection wiring 72 preferably has a plan-view area greater than that of the wiring plug electrode 80. The low-potential connection wiring 72 is electrically connected to the first inner end 24 of the low-potential coil 22.

The lead-out wiring 73 is formed in the interlayer insulating layer 57 in a region between the semiconductor chip 41 and the penetration wiring 71. In this embodiment, the lead-out wiring 73 is formed in the first interlayer insulating layer 57 counted from the lowermost insulating layer 55. The lead-out wiring 73 includes a first end portion on one side, a second end portion on the other side, and a wiring portion connecting the first end portion and the second end portion. The first end portion of the lead-out wiring 73 is located in the region between the semiconductor chip 41 and the lower end of the penetration wiring 71. The second end portion of the lead-out wiring 73 is located in the region between the semiconductor chip 41 and the low-potential connection wiring 72. The wiring portion extends along the first main surface 42 of the semiconductor chip 41 and extends in a strip shape in a region between the first end portion and the second end portion.

The first connection plug electrode 74 is formed in the interlayer insulating layer 57 in a region between the penetration wiring 71 and the lead-out wiring 73, and is electrically connected to first end portions of the penetration wiring 71 and the lead-out wiring 73. The second connection plug electrode 75 is formed in the interlayer insulating layer 57 in a region between the low-potential connection wiring 72 and the lead-out wiring 73, and is electrically connected to second end portions of the low-potential connection wiring 72 and the lead-out wiring 73.

The plurality of pad plug electrodes 76 are formed in the uppermost insulating layer 56 in a region between the low-potential terminal 11 (the first low-potential terminal 11A) and the penetration wiring 71, and are electrically connected to the upper end portions of the low-potential terminal 11 and the penetration wiring 71, respectively. The plurality of substrate plug electrodes 77 are formed in the lowermost insulating layer 55 in a region between the semiconductor chip 41 and the lead-out wiring 73. In this embodiment, the substrate plug electrodes 77 are formed in a region between the semiconductor chip 41 and the first end portion of the lead-out wiring 73, and are electrically connected to the semiconductor chip 41 and the first end portion of the lead-out wiring 73, respectively.

Referring to FIGS. 6 and 7, the plurality of first high-potential wirings 33 are electrically connected to the corresponding high-potential terminals 12A to 12D and the second inner ends 27 of the corresponding transformers 21A to 21D (the high-potential coils 23). The plurality of first high-potential wirings 33 have a similar structure. In the following, a structure of the first high-potential wiring 33 connected to the first high-potential terminal 12A and the first transformer 21A will be described as an example. Structures of other first high-potential wirings 33 are similar to the structure of the first high-potential wiring 33 connected to the first transformer 21A, and therefore, descriptions thereof will be omitted.

The first high-potential wiring 33 includes a high-potential connection wiring 81 and one or more (a plurality of, in this embodiment) pad plug electrodes 82. The high-potential connection wiring 81 and the pad plug electrode 82 are preferably formed of the same conductive material as the low-potential coil 22 or the like. In other words, each of the high-potential connection wiring 81 and the pad plug electrode 82 preferably includes a barrier layer and a main body layer, like the low-potential coil 22 or the like.

The high-potential connecting wiring 81 is formed in the second inner region 67 of the high-potential coil 23 inside the same interlayer insulating layer 57 as the high-potential coil 23. The high-potential connection wiring 81 is formed in an island shape to face the high-potential terminal 12 (the first high-potential terminal 12A) in the normal direction Z. The high-potential connection wiring 81 is electrically connected to the second inner end 27 of the high-potential coil 23. The high-potential connection wiring 81 is formed so as to be spaced apart from the low-potential connection wiring 72 in a plan view and does not face the low-potential connection wiring 72 in the normal direction Z. This increases an insulation distance between the low-potential connection wiring 72 and the high-potential connection wiring 81, thereby increasing the dielectric strength voltage of the insulating layer 51.

The plurality of pad plug electrodes 82 are formed in the uppermost insulating layer 56 in a region between the high-potential terminal 12 (the first high-potential terminal 12A) and the high-potential connection wiring 81, and are electrically connected to the high-potential terminal 12 and the high-potential connection wiring 81. Each of the plurality of pad plug electrodes 82 has a plan-view area that is smaller than that of the high-potential connection wiring 81 in a plan view.

Referring to FIG. 7, a distance D1 between the low-potential terminal 11 and the high-potential terminal 12 preferably exceeds a distance D2 between the low-potential coil 22 and the high-potential coil 23 (D2<D1). The distance D1 preferably exceeds a total thickness DT of the plurality of interlayer insulating layers 57 (DT<D 1). A ratio D2/D1 of the distance D2 to the distance D1 may be 0.01 or more and 0.1 or less. The distance D1 is preferably 100 μm or more and 500 μm or less. The distance D2 may be 1 μm or more and 50 μm or less. The distance D2 is preferably 5 μm or more and 25 μm or less. Values of the distance D1 and the distance D2 are optional and are adjusted appropriately according to the dielectric strength voltage to be achieved.

Referring to FIGS. 6 and 7, the semiconductor device 5 includes a dummy pattern 85 embedded in the insulating layer 51 so as to be located around the transformers 21A to 21D in a plan view.

The dummy pattern 85 is formed in a pattern (discontinuous pattern) different from the high-potential coil 23 and the low-potential coil 22 and is independent of the transformers 21A to 21D. In other words, the dummy pattern 85 does not function as the transformers 21A to 21D. The dummy pattern 85 is formed as a shielding conductor layer that shields the electric field between the low-potential coil 22 and the high-potential coil 23 in the transformers 21A to 21D, and suppresses the electric field from being concentrated on the high-potential coil 23. In this embodiment, the dummy pattern 85 is arranged with a line density per unit area equal to that of the high-potential coil 23. The expression “the line density of the dummy pattern 85 being equal to that of the high-potential coil 23” means that the line density of the dummy pattern 85 falls within a range of ±20% of the line density of the high-potential coil 23.

A depth position of the dummy pattern 85 inside the insulating layer 51 is optional and is adjusted according to an electric field intensity to be attenuated. The dummy pattern 85 is preferably formed in a region closer to the high-potential coil 23 than to the low-potential coil 22 in the normal direction Z. The expression “the dummy pattern 85 being closer to the high-potential coil 23 in the normal direction Z” means that the distance between the dummy pattern 85 and the high-potential coil 23 in the normal direction Z is less than the distance between the dummy pattern 85 and the low-potential coil 22.

In this case, the concentration of the electric field on the high-potential coil 23 may be appropriately suppressed. As the distance between the dummy pattern 85 and the high-potential coil 23 in the normal direction Z is decreased, the concentration of the electric field on the high-potential coil 23 may further be suppressed. The dummy pattern 85 is preferably formed in the same interlayer insulating layer 57 as the high-potential coil 23. In this case, the concentration of the electric field on the high-potential coil 23 may be further appropriately suppressed. The dummy pattern 85 includes a plurality of dummy patterns with different electrical states. The dummy pattern 85 may include a high-potential dummy pattern.

The depth position of the high-potential dummy pattern 86 inside the insulating layer 51 is optional and is adjusted according to the electric field intensity to be attenuated. The high-potential dummy pattern 86 is preferably formed in a region closer to the high-potential coil 23 than to the low-potential coil 22 in the normal direction Z. The expression “the high-potential dummy pattern 86 being closer to the high-potential coil 23 in the normal direction Z” means that the distance between the high-potential dummy pattern 86 and the high-potential coil 23 in the normal direction Z is less than the distance between the high-potential dummy pattern 86 and the low-potential coil 22.

The dummy pattern 85 includes a floating dummy pattern formed in an electrically floating state inside the insulating layer 51 so as to be positioned around the transformers 21A to 21D.

In this embodiment, the floating dummy pattern is arranged in a dense line shape so as to partially cover and partially expose a region around the high-potential coil 23 in a plan view. The floating dummy pattern may be formed to have ends or to have no ends.

The depth position of the floating dummy pattern inside the insulating layer 51 is optional and is adjusted according to the electric field intensity to be attenuated.

The number of floating lines is optional and may be adjusted according to the electric field to be attenuated. The floating dummy pattern may be constituted with a plurality of floating lines.

Referring to FIG. 7, the semiconductor device 5 includes a second functional device 60 formed on the first main surface 42 of the semiconductor chip 41 in a device region 62. The second functional device 60 is formed using a surface layer portion of the first main surface 42 of the semiconductor chip 41 and/or a region above the first main surface 42 of the semiconductor chip 41, and is covered with the insulating layer 51 (the lowermost insulating layer 55). In FIG. 7, the second functional device 60 is shown in a simplified manner by a dashed line drawn in the surface layer portion of the first main surface 42.

The second functional device 60 is electrically connected to the low-potential terminal 11 via a low-potential wiring, and is electrically connected to the high-potential terminal 12 via a high-potential wiring. The low-potential wiring has the same structure as that of the first low-potential wiring 31 (the second low-potential wiring 32), except that it is arranged inside the insulating layer 51 so as to be connected to the second functional device 60. The high-potential wiring has the same structure as that of the first high-potential wiring 33 (the second high-potential wiring 34), except that it is arranged inside the insulating layer 51 so as to be connected to the second functional device 60. Detailed descriptions of the low-potential wiring and the high-potential wiring related to the second functional device 60 will be omitted.

The second functional device 60 may include at least one of a passive device, a semiconductor rectifying device, or a semiconductor switching device. The second functional device 60 may include a circuit network in which two or more of the passive device, the semiconductor rectifying device, and the semiconductor switching device are selectively combined with each other. The circuit network may form a portion or the entirety of an integrated circuit.

The passive device may include a semiconductor passive device. The passive device may include either or both of a resistor and a capacitor. The semiconductor rectifying device may include at least one of a pn junction diode, a PIN diode, a Zener diode, a Schottky barrier diode, or a fast recovery diode. The semiconductor switching device may include at least one of a BJT (Bipolar Junction Transistor), a MISFET (Metal Insulator Semiconductor Field Effect Transistor), an IGBT (Insulated Gate Bipolar Junction Transistor), or a JFET (Junction Field Effect Transistor).

Referring to FIGS. 5 to 7, the semiconductor device 5 further includes a seal conductor 61 embedded in the insulating layer 51. The seal conductor 61 is embedded in the insulating layer 51 in a wall shape so as to be spaced apart from the insulating sidewalls 53A to 53D in a plan view, and is configured to divide the insulating layer 51 into a device region 62 and an outer region 63. The seal conductor 61 suppresses introduction of moisture and cracks from the outer region 63 into the device region 62.

The device region 62 is a region including the first functional device 45 (the plurality of transformers 21), the second functional device 60, the plurality of low-potential terminals 11, the plurality of high-potential terminals 12, the first low-potential wiring 31, the second low-potential wiring 32, the first high-potential wiring 33, the second high-potential wiring 34, and the dummy pattern 85. The outer region 63 is a region outside the device region 62.

The seal conductor 61 is electrically isolated from the device region 62. Specifically, the seal conductor 61 is electrically isolated from the first functional device 45 (the plurality of transformers 21), the second functional device 60, the plurality of low-potential terminals 11, the plurality of high-potential terminals 12, the first low-potential wiring 31, the second low-potential wiring 32, the first high-potential wiring 33, the second high-potential wiring 34, and the dummy pattern 85. More specifically, the seal conductor 61 is fixed in an electrically floating state. The seal conductor 61 does not form a current path leading to the device region 62.

The seal conductor 61 is formed in a strip shape along the insulating sidewalls 53 to 53D in a plan view. In this embodiment, the seal conductor 61 is formed in a quadrangular ring shape (specifically, a rectangular ring shape) in a plan view. As a result, the seal conductor 61 defines a quadrangular (specifically, rectangular) device region 62 in a plan view. The seal conductor 61 also defines a quadrangular (specifically, rectangular) outer region 63 that surrounds the device region 62 in a plan view.

Specifically, the seal conductor 61 has an upper end portion on the side of the insulating main surface 52, a lower end portion on the side of the semiconductor chip 41, and a wall portion extending in a wall shape between the upper end portion and the lower end portion. In this embodiment, the upper end portion of the seal conductor 61 is formed at a distance from the insulating main surface 52 toward the semiconductor chip 41 and is located inside the insulating layer 51. In this embodiment, the upper end portion of the seal conductor 61 is covered by the uppermost insulating layer 56. The upper end portion of the seal conductor 61 may be covered by one or more interlayer insulating layers 57. The upper end portion of the seal conductor 61 may be exposed from the uppermost insulating layer 56. The lower end portion of the seal conductor 61 is formed at a distance from the semiconductor chip 41 toward the upper end.

Thus, in this embodiment, the seal conductor 61 is embedded in the insulating layer 51 so as to be located on the side of the semiconductor chip 41 with respect to the plurality of low-potential terminals 11 and the plurality of high-potential terminals 12. Further, inside the insulating layer 51, the seal conductor 61 faces the first functional device 45 (the plurality of transformers 21), the first low-potential wiring 31, the second low-potential wiring 32, the first high-potential wiring 33, the second high-potential wiring 34, and the dummy pattern 85 in a direction parallel to the insulating main surface 52. Inside the insulating layer 51, the seal conductor 61 may face a portion of the second functional device 60 in a direction parallel to the insulating main surface 52.

The seal conductor 61 includes a plurality of seal plug conductors 64 and one or more (a plurality of, in this embodiment) seal via conductors 65. The number of seal via conductors 65 is optional. The uppermost seal plug conductor 64 among the plurality of seal plug conductors 64 forms the upper end portion of the seal conductor 61. Each of the plurality of seal via conductors 65 forms the lower end portion of the seal conductor 61. The seal plug conductors 64 and the seal via conductors 65 are preferably formed of the same conductive material as the low-potential coil 22. In other words, each of the seal plug conductors 64 and the seal via conductors 65 preferably includes a barrier layer and a main body layer, like the low-potential coil 22 or the like.

The plurality of seal plug conductors 64 are embedded in the plurality of interlayer insulating layers 57, respectively, and are formed in a quadrangular ring shape (specifically, a rectangular ring shape) surrounding the device region 62 in a plan view. The plurality of seal plug conductors 64 are stacked from the lowermost insulating layer 55 to the uppermost insulating layer 56 so as to be connected to each other. The number of stacked seal plug conductors 64 is equal to the number of stacked interlayer insulating layers 57. Of course, one or more seal plug conductors 64 may be formed to penetrate the plurality of interlayer insulating layers 57.

As long as a single ring-shaped seal conductor 61 is formed by an assembly of the plurality of seal plug conductors 64, it is not necessary for all of the plurality of seal plug conductors 64 to be formed in a ring shape. For example, at least one of the plurality of seal plug conductors 64 may be formed in an ended shape. Further, at least one of the plurality of seal plug conductors 64 may be divided into a plurality of strip-shaped portions with ends. However, in consideration of a risk of introducing moisture and cracks to the device region 62, it is preferable that the plurality of seal plug conductors 64 is formed in an endless shape (ring shape).

Each of the plurality of seal via conductors 65 is formed in a region between the semiconductor chip 41 and the seal plug conductors 64 in the lowermost insulating layer 55. The plurality of seal via conductors 65 are formed to be spaced apart from the semiconductor chip 41 and connected to the seal plug conductors 64. The plurality of seal via conductors 65 have a plan-view area smaller than that of the seal plug conductor 64. In a case in which a single seal via conductor 65 is formed, the single seal via conductor 65 may have a plan-view area equal to or larger than that of the seal plug conductor 64.

A width of the seal conductor 61 may be 0.1 μm or more and 10 μm or less. The width of the seal conductor 61 is preferably 1 μm or more and 5 μm or less. The width of the seal conductor 61 is defined by a width in a direction perpendicular to the direction in which the seal conductor 61 extends.

Referring to FIGS. 7 and 8, the semiconductor device 5 further includes an isolated structure 130 interposed between the semiconductor chip 41 and the seal conductor 61 to electrically isolate the seal conductor 61 from the semiconductor chip 41. The isolated structure 130 preferably includes an insulator. In this embodiment, the isolated structure 130 is made of a field insulating film 131 formed on the first main surface 42 of the semiconductor chip 41.

The field insulating film 131 includes at least one of an oxide film (silicon oxide film) or a nitride film (silicon nitride film). The field insulating film 131 is preferably made of a local oxidation of silicon (LOCOS) film, which is an example of an oxide film formed by oxidizing the first main surface 42 of the semiconductor chip 41. A thickness of the field insulating film 131 is optional as long as it may insulate the semiconductor chip 41 from the seal conductor 61. The thickness of the field insulating film 131 may be 0.1 μm or more and 5 μm or less.

The isolated structure 130 is formed on the first main surface 42 of the semiconductor chip 41 and extends in a strip shape along the seal conductor 61 in a plan view. In this embodiment, the isolated structure 130 is formed in a quadrangular ring shape (specifically, a rectangular ring shape) in a plan view. The isolated structure 130 has a connection portion 132 to which the lower end portion (the seal via conductor 65) of the seal conductor 61 is connected. The connection portion 132 may form an anchor portion where the lower end portion (the seal via conductor 65) of the seal conductor 61 is embedded toward the semiconductor chip 41. Of course, the connection portion 132 may be formed to be flush with the main surface of the isolated structure 130.

The isolated structure 130 includes an inner end portion 130A on the side of the device region 62, an outer end portion 130B on the side of the outer region 63, and a main body portion 130C between the inner end portion 130A and the outer end portion 130B. The inner end portion 130A defines a region in which the second functional device 60 is formed (that is, the device region 62) in a plan view. The inner end portion 130A may be formed integrally with an insulating film (not shown) formed on the first main surface 42 of the semiconductor chip 41.

The outer end portion 130B is exposed from the chip sidewalls 44A to 44D of the semiconductor chip 41 and is continuous with the chip sidewalls 44A to 44D of the semiconductor chip 41. More specifically, the outer end portion 130B is formed to be flush with the chip sidewalls 44A to 44D of the semiconductor chip 41. The outer end portion 130B forms a flush ground surface between the chip sidewalls 44A to 44D of the semiconductor chip 41 and the insulating sidewalls 53A to 53D of the insulating layer 51. Of course, in other embodiments, the outer end portion 130B may be formed inside the first main surface 42 at a distance from the chip sidewalls 44A to 44D.

The main body portion 130C has a flat surface extending substantially parallel to the first main surface 42 of the semiconductor chip 41. The main body portion 130C has a connection portion 132 to which the lower end portion (the seal via conductor 65) of the seal conductor 61 is connected. The connection portion 132 is formed in a portion of the main body portion 130C spaced apart from the inner end portion 130A and the outer end portion 130B. The isolated structure 130 may take various forms in addition to the field insulating film 131.

Referring to FIG. 7, the semiconductor device 5 further includes an inorganic insulating layer 140 formed on the insulating main surface 52 of the insulating layer 51 so as to cover the seal conductor 61. The inorganic insulating layer 140 may also be referred to as a passivation layer. The inorganic insulating layer 140 protects the insulating layer 51 and the semiconductor chip 41 from above the insulating main surface 52.

In this embodiment, the inorganic insulating layer 140 has a stacked structure composed of a first inorganic insulating layer 141 and a second inorganic insulating layer 142. The first inorganic insulating layer 141 may contain silicon oxide. The first inorganic insulating layer 141 preferably contains USG (undoped silicate glass), which is silicon oxide without impurities. A thickness of the first inorganic insulating layer 141 may be 50 nm or more and 5,000 nm or less. The second inorganic insulating layer 142 may contain silicon nitride. A thickness of the second inorganic insulating layer 142 may be 500 nm or more and 5,000 nm or less. Increasing the total thickness of the inorganic insulating layer 140 may increase the dielectric strength voltage on the high-potential coil 23.

When the first inorganic insulating layer 141 is made of USG and the second inorganic insulating layer 142 is made of silicon nitride, the dielectric breakdown voltage (V/cm) of USG exceeds the dielectric breakdown voltage (V/cm) of the silicon nitride. Therefore, when the inorganic insulating layer 140 is thickened, it is preferable that the first inorganic insulating layer 141 is thicker than the second inorganic insulating layer 142.

The first inorganic insulating layer 141 may contain at least one of BPSG (boron-doped phosphor silicate glass) or PSG (phosphorus silicate glass), which are examples of the silicon oxide. However, in this case, since impurities (boron or phosphorus) are contained in the silicon oxide, it is particularly preferable to form the first inorganic insulating layer 141 with USG in order to increase the dielectric strength voltage on the high-potential coil 23. Of course, the inorganic insulating layer 140 may have a single-layer structure composed of either the first inorganic insulating layer 141 or the second inorganic insulating layer 142.

The inorganic insulating layer 140 covers the entire seal conductor 61, and has a plurality of low-potential pad openings 143 and a plurality of high-potential pad openings 144 formed in a region outside the seal conductor 61. The plurality of low-potential pad openings 143 expose the plurality of low-potential terminals 11, respectively. The plurality of high-potential pad openings 144 expose the plurality of high-potential terminals 12, respectively. The inorganic insulating layer 140 may have an overlapping portion that rides up onto a peripheral edge portion of the low-potential terminal 11. The inorganic insulating layer 140 may have an overlapping portion that rides up onto the peripheral edge of the high-potential terminal 12.

The semiconductor device 5 further includes an organic insulating layer 145 formed on the inorganic insulating layer 140. The organic insulating layer 145 may contain a photosensitive resin. The organic insulating layer 145 may contain at least one of polyimide, polyamide, or polybenzoxazole. In this embodiment, the organic insulating layer 145 contains polyimide. A thickness of the organic insulating layer 145 may be 1 μm or more and 50 μm or less.

The thickness of the organic insulating layer 145 preferably exceeds the total thickness of the inorganic insulating layer 140. Further, the total thickness of the inorganic insulating layer 140 and the organic insulating layer 145 is preferably equal to or greater than the distance D2 between the low-potential coil 22 and the high-potential coil 23. In this case, the total thickness of the inorganic insulating layer 140 is preferably 2 μm or more and 10 μm or less. Further, the thickness of the organic insulating layer 145 is preferably 5 μm or more and 50 μm or less. With these structures, it is possible to prevent the inorganic insulating layer 140 and the organic insulating layer 145 from becoming thicker, and the dielectric strength voltage on the high-potential coil 23 may be appropriately increased by a stacked film of the inorganic insulating layer 140 and the organic insulating layer 145.

The organic insulating layer 145 includes a first portion 146 covering a low-potential-side region and a second portion 147 covering a high-potential-side region. The first portion 146 covers the seal conductor 61 with the inorganic insulating layer 140 sandwiched therebetween. The first portion 146 has a plurality of low-potential terminal openings 148 that expose the plurality of low-potential terminals 11 (the low-potential pad openings 143) in a region outside the seal conductor 61. The first portion 146 may have an overlapping portion that rides up onto the peripheral edge (the overlapping portion) of the low-potential pad opening 143.

The second portion 147 is formed at a distance from the first portion 146 to expose the inorganic insulating layer 140 between the second portion 147 and the first portion 146. The second portion 147 has a plurality of high-potential terminal openings 149 that expose the plurality of high-potential terminals 12 (the high-potential pad openings 144), respectively. The second portion 147 may have an overlapping portion that rides up onto the peripheral edge (the overlapping portion) of the high-potential pad opening 144.

The second portion 147 collectively covers the transformers 21A to 21D and the dummy pattern 85. Specifically, the second portion 147 collectively covers the plurality of high-potential coils 23, the plurality of high-potential terminals 12, the first high-potential dummy pattern 87, the second high-potential dummy pattern 88, and the floating dummy pattern 121.

The embodiment of the present disclosure may be implemented in other forms. In the above-described embodiment, an example in which the first functional device 45 and the second functional device 60 are formed has been described. However, a form in which only the second functional device 60 is provided without the first functional device 45 may also be adopted. In this case, the dummy pattern 85 may be removed. According to this structure, the second functional device 60 may achieve the same effects as those described in the first embodiment (excluding the effects related to the dummy pattern 85).

That is, when a voltage is applied to the second functional device 60 via the low-potential terminal 11 and the high-potential terminal 12, it is possible to suppress an undesired electrical connection between the high-potential terminal 12 and the seal conductor 61. Further, when a voltage is applied to the second functional device 60 via the low-potential terminal 11 and the high-potential terminal 12, it is possible to suppress an undesired electrical connection between the low-potential terminal 11 and the seal conductor 61.

In the above-described embodiment, an example in which the second functional device 60 is formed has been described. However, the second functional device 60 is not necessarily required and may be removed.

In the above-described embodiment, an example in which the dummy pattern 85 is formed has been described. However, the dummy pattern 85 is not necessarily required and may be removed.

In the above-described embodiment, an example in which the first functional device 45 is of a multi-channel type including a plurality of transformers 21 has been described. However, a first functional device 45 of a single-channel type including a single transformer 21 may also be adopted.

### Transformer Arrangement

FIG. 9 is a plan view (top view) that schematically shows an example of a transformer arrangement in a two-channel type transformer chip 300 (corresponding to the aforementioned semiconductor device 5). The transformer chip 300 in this figure includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one end of a secondary-side coil L1s that forms the first transformer 301, and pads c1 and d1 are connected to the other end of the secondary-side coil L1s. The pads a2 and b2 are connected to one end of a secondary-side coil L2s that forms the second transformer 302, and the pads c1 and d1 are connected to the other end of the secondary-side coil L2s.

The pads a3 and b3 are connected to one end of a secondary-side coil L3s that forms the third transformer 303, and the pads c2 and d2 are connected to the other end of the secondary-side coil L3s. The pads a4 and b4 are connected to one end of a secondary-side coil L4s that forms the fourth transformer 304, and the pads c2 and d2 are connected to the other end of the secondary-side coil L4s.

The primary-side coil that forms the first transformer 301, the primary-side coil that forms the second transformer 302, the primary-side coil that forms the third transformer 303, and the primary-side coil that forms the fourth transformer 304 are not shown in the figures. However, the primary-side coils basically have the same configuration as those of the secondary-side coils L1s to L4s, and are arranged directly below the secondary-side coils L1s to L4s, respectively, so as to face the secondary-side coils L1s to L4s.

That is, the pads a5 and b5 are connected to one end of the primary-side coil that forms the first transformer 301, and the pads c3 and d3 are connected to the other end of the primary-side coil. Further, the pads a6 and b6 are connected to one end of the primary-side coil that forms the second transformer 302, and the pads c3 and d3 are connected to the other end of the primary-side coil.

Further, the pads a7 and b7 are connected to one end of the primary-side coil that forms the third transformer 303, and the pads c4 and d4 are connected to the other end of the primary-side coil. The pads a8 and b8 are connected to one end of the primary-side coil that forms the fourth transformer 304, and the pads c4 and d4 are connected to the other end of the primary-side coil.

However, the pads a5 to a8, the pads b5 to b8, the pads c3 and c4, and the pads d3 and d4 are led out from the inside of the transformer chip 300 to the surface thereof through vias (not shown).

Among the plurality of pads, the pads a1 to a8 correspond to first current supply pads, the pads b1 to b8 correspond to first voltage measurement pads, the pads c1 to c4 correspond to second current supply pads, and the pads d1 to d4 correspond to second voltage measurement pads.

Therefore, according to the transformer chip 300 of this configuration example, a series resistance component of each coil may be accurately measured during a defective product inspection. Therefore, it is possible to not only reject defective products in which a disconnection has occurred in each coil, but also to appropriately reject defective products in which a resistance value abnormality (for example, a short circuit between coils) has occurred in each coil, thereby making it possible to prevent defective products from being released to the market beforehand.

In a case of the transformer chip 300 that has passed the above-mentioned defective product inspection, the plurality of pads may be used as a means for connecting a primary chip and a secondary chip (for example, the controller chip 210 and the driver chip 220 described above).

Specifically, the pads a1 and b1, the pads a2 and b2, the pads a3 and b3, and the pads a4 and b4 may be connected to signal input terminals or signal output terminals of the secondary chip, respectively. In addition, the pads c1 and d1 and the pads c2 and d2 may be connected to common voltage application terminals (GND2) of the secondary chip, respectively.

On the other hand, the pads a5 and b5, the pads a6 and b6, the pads a7 and b7, and the pads a8 and b8 may be connected to signal input terminals or signal output terminals of the primary chip, respectively. In addition, the pads c3 and d3 and the pads c4 and d4 may be connected to common voltage application terminals (GND1) of the primary chip, respectively.

As shown in FIG. 9, the first to fourth transformers 301 to 304 are arranged in a coupled manner for their respective signal transmission directions. Referring to this figure, for example, the first transformer 301 and the second transformer 302, which transmit signals from the primary chip to the secondary chip, are coupled to each other as a first pair by a first guard ring 305. Further, the third transformer 303 and the fourth transformer 304, which transmit signals from the secondary chip to the primary chip, are coupled to each other as a second pair by a second guard ring 306.

The reason for such coupling is to ensure a dielectric breakdown voltage between the primary-side coil and the secondary-side coil in the case in which the primary-side coils and the secondary-side coils that respectively form the first transformer 301 to the fourth transformer 304 are stacked one above another in the up-down direction of the substrate of the transformer chip 300. However, the first guard ring 305 and the second guard ring 306 are not necessarily essential components.

The first guard ring 305 and the second guard ring 306 may be connected to low-impedance wirings such as ground terminals via pads e1 and e2, respectively.

In the transformer chip 300, the pads c1 and d1 are shared by the secondary-side coil L1s and the secondary-side coil L2s. The pads c2 and d2 are shared by the secondary-side coil L3s and the secondary-side coil L4s. The pads c3 and d3 are shared by the primary-side coil L1p and the primary-side coil L2p. The pads c4 and d4 are shared by the corresponding primary-side coils. This configuration reduces the number of pads, making it possible to miniaturize the transformer chip 300.

As shown in FIG. 9, the primary-side coil and the secondary-side coil that form each of the first transformer 301 to the fourth transformer 304 are preferably wound so as to form a rectangular shape (or a track shape with rounded corners) in a plan view of the transformer chip 300. With this configuration, it is possible to increase the region where the primary-side coil and the secondary-side coil overlap, thus improving transmission efficiency of the transformers.

Of course, the transformer arrangement in this figure is merely one example. The number, shape, and arrangement of the coils, and the arrangement of the pads are optional. Further, the chip structure and the transformer arrangement described so far may be applied to all semiconductor devices in which coils are integrated on a semiconductor chip.

### Insulated Switch (Comparative Example)

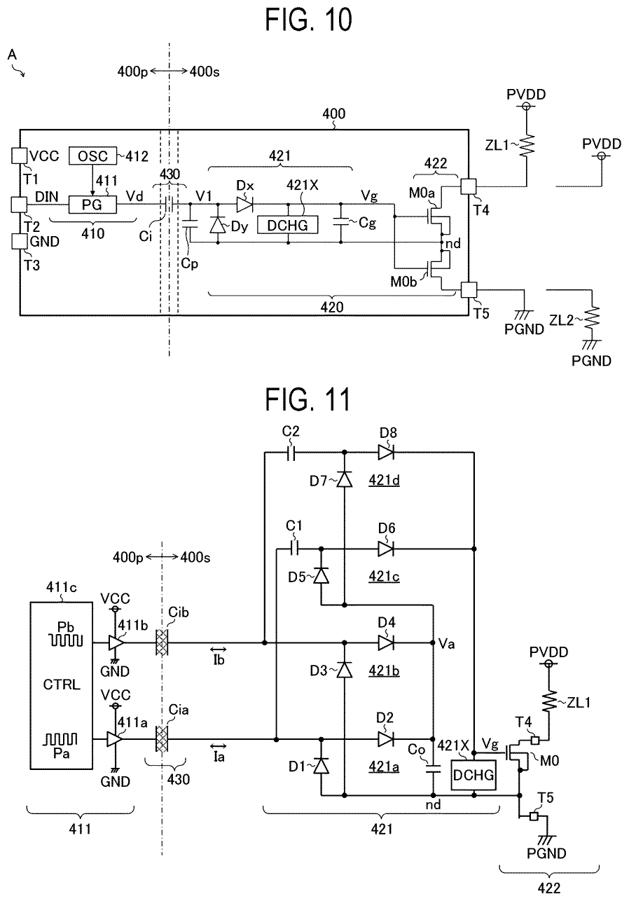

FIG. 10 shows a comparative example of an insulated switch 400 (that is, an example of a circuit configuration to be compared with the embodiments described below). The insulated switch 400 of this comparative example transmits a pulse signal from a primary-side circuit system 400p (VCC-GND system) to a secondary circuit system 400s (PVDD-PGND system) while providing insulation between the primary-side circuit system 400p and the secondary circuit system 400s.

The insulated switch 400 may be mounted on an electronic device A together with a load ZL1 or ZL2. The electronic device A may be, for example, an industrial machine or an in-vehicle device. The insulated switch 400 may be integrated into a semiconductor integrated circuit device (a so-called insulated switch IC) and may be provided to the market. The insulated switch 400 is also called an insulation relay.

The insulated switch 400 includes external terminals T1 to T5 as means for establishing electrical connection with the outside of the device. The external terminal T1 is connected to a terminal to which a power supply voltage VCC is applied. The external terminal T2 is connected to a terminal to which an input pulse signal DIN is applied. The external terminal T3 is connected to a terminal to which a ground voltage GND is applied. The external terminal T4 is connected to a terminal to which a power supply voltage PVDD is applied directly or via the load ZL1. The external terminal T5 is connected to a terminal to which a ground voltage PGND is applied directly or via the load ZL2.

The insulated switch 400 further includes a primary-side circuit 410, a secondary-side circuit 420, and an insulation circuit 430.

The primary-side circuit 410 is provided in the primary-side circuit system 400p. Referring to the figure, the primary-side circuit 410 includes a pulse generation circuit 411 and an oscillation circuit 412.

The pulse generation circuit 411 outputs a transmission pulse signal Vd to a first terminal of an insulation capacitor Ci in response to the input pulse signal DIN. For example, the transmission pulse signal Vd may be driven between the power supply voltage VCC and the ground voltage GND in a pulse manner.

The oscillation circuit 412 supplies a clock signal to the pulse generation circuit 411. The transmission pulse signal Vd is driven in synchronization with the clock signal output from the oscillation circuit 412 in a pulse manner.

The secondary-side circuit 420 is provided in the secondary circuit system 400s. Referring to the figure, the secondary-side circuit 420 includes a switch drive circuit 421 and a switch circuit 422.

The switch drive circuit 421 generates a switch drive signal Vg in response to the reception pulse signal V1. Referring to the figure, the switch drive circuit 421 includes diodes Dx and Dy, a capacitor Cg, and a discharge circuit 421X.

An anode of the diode Dx and a cathode of the diode Dy are connected to an application terminal for the reception pulse signal V1. A cathode of the diode Dx, and a first terminal of each of the capacitor Cg and the discharge circuit 421X are all connected to an application terminal for the switch drive signal Vg. An anode of the diode Dy, and a second terminal of each of the capacitor Cg and the discharge circuit 421X are all connected to a reference node nd. The capacitor Cg may be a parasitic capacitor associated between a gate and a source of each of transistors M0a and M0b, which will be described later. The diodes Dx and Dy and the capacitor Cg rectify and smooth the reception pulse signal V1 to generate the switch drive signal Vg.

The switch circuit 422 is connected between the external terminal T4 and the external terminal T5 and is turned on and off by the switch drive signal Vg. The external terminal T4 corresponds to a first node. The external terminal T5 corresponds to a second node.

For example, the switch circuit 422 includes the transistors M0a and M0b that connect and disconnect the external terminal T4 and the external terminal T5 in response to the switch drive signal Vg. The transistors M0a and M0b may be, for example, N-channel MOS (metal oxide semiconductor) field effect transistors.

A drain of the transistor M0a is connected to the external terminal T4. A drain of the transistor M0b is connected to the external terminal T5. Sources and back gates of the transistors M0a and M0b are both connected to the reference node nd. Gates of the transistors M0a and M0b are both connected to the application terminal for the switch drive signal Vg. The transistors M0a and M0b may be understood as output transistors whose gates are connected to the application terminal for the switch drive signal Vg.

In a first connection mode, the external terminal T4 is connected to the application terminal for the power supply voltage PVDD via the load ZL1, and the external terminal T5 is directly connected to the application terminal for the ground voltage PGND. In this case, the switch circuit 422 functions as a lower switch (sink output type).

In a second connection mode, the external terminal T5 is connected to the application terminal for the ground voltage PGND via the load ZL2, and the external terminal T4 is directly connected to the application terminal for the power supply voltage PVDD. In this case, the switch circuit 422 functions as an upper switch (source output type).

The insulation circuit 430 transmits the transmission pulse signal Vd as the reception pulse signal V1 while galvanically insulating the pulse generation circuit 411 and the switch drive circuit 421 from each other. Referring to the figure, the insulation circuit 430 includes an insulation capacitor Ci.

The insulation capacitor Ci is connected between the pulse generation circuit 411 and the switch drive circuit 421. Referring to the figure, a first terminal of the insulation capacitor Ci is connected to an application terminal for the transmission pulse signal Vd, and a second terminal of the insulation capacitor Ci is connected to an application terminal for the reception pulse signal V1.

Next, a basic operation of the insulated switch 400 will be described. During a high-level period of the input pulse signal DIN, the transmission pulse signal Vd applied to the first terminal of the insulation capacitor Ci is driven in a pulse manner. At this time, the reception pulse signal V1 is transmitted to the second terminal of the insulation capacitor Ci. The reception pulse signal V1 is rectified and smoothed, thereby raising the switch drive signal Vg to a signal level higher than an on-threshold voltage Vth of each of the transistors M0a and M0b. Therefore, the transistors M0a and M0b are turned on, thereby allowing a drive current to be supplied to the load ZL1 or ZL2.

On the other hand, during a low-level period of the input pulse signal DIN, the pulse drive of the transmission pulse signal Vd is stopped. Therefore, the reception pulse signal V1 is at a low level ( [symbol] PGND). At this time, the discharge circuit 421X operates to lower the switch drive signal Vg to a signal level lower than the on-threshold voltage Vth of each of the transistors M0a and M0b. As a result, the transistors M0a and M0b are turned off, and no drive current is supplied to the load ZL1 or ZL2.

The switch drive circuit 421 is supplied with power via the insulation circuit 430. That is, the switch drive circuit 421 generates the switch drive signal Vg using the reception pulse signal V1 transmitted via the insulation circuit 430 as a power source. Conversely, the switch drive circuit 421 may generate the switch drive signal Vg without being supplied with power from the secondary circuit system 400s.

In this way, the insulated switch 400 of this comparative example transmits a pulse signal from the primary-side circuit system 400p to the secondary circuit system 400s while insulating the primary-side circuit system 400p and the secondary circuit system 400s from each other by a capacitive coupling using the insulation capacitor Ci.

### Considerations Regarding Signal Attenuation

A parasitic capacitor Cp may exist between the application terminal for the reception pulse signal V1 (that is, an input pad of the secondary-side circuit 420) and the external terminal T5. A capacitance of the insulation capacitor Ci integrated into the insulation circuit 430 is generally smaller than that of the parasitic capacitor Cp (for example, Ci=0.1 pF, and Cp=1 pF). Accordingly, the reception pulse signal V1 may be significantly attenuated from the transmission pulse signal Vd and transmitted. Therefore, in the insulated switch 400 of this comparative example, it may be difficult to raise the switch drive signal Vg to a signal level higher than the on-threshold voltage Vth of each of the transistors M0a and M0b.

In the related art, DMOS (double-diffused MOS) devices or CMOS (complementary MOS) devices are widely used as the transistors M0a and M0b. When the power supply voltage PVDD of the secondary circuit system 400 s is about 10 to 40 V, the selection of the aforementioned devices does not cause any particular problems.

However, in recent years, there has been a demand or application for applying a high voltage of as high as 600 V as the power supply voltage PVDD. The aforementioned DMOS or CMOS devices may not be able to withstand such a high voltage. Therefore, in order to meet the above demand, it is necessary to use, as the transistors M0a and M0b, devices with a higher breakdown voltage than DMOS or CMOS devices, for example, GaN devices such as GaN-HEMTs (high electron mobility transistors), or SiC devices such as SiC-MOSFETs.

However, the on-threshold voltage of the GaN device or the SiC device is higher than that of the DMOS device or the CMOS device. Therefore, a mechanism for raising the high level of the switch drive signal Vg is required.

In view of the above considerations, an embodiment capable of reliably turning on the transistors M0a and M0b even when they are of a capacitively coupled type will be proposed below.

### Insulated Switch (First Embodiment)

FIG. 11 shows a first embodiment of the insulated switch 400. The insulated switch 400 of this embodiment is based on the comparative example (FIG. 10) described above, with modifications made to the pulse generation circuit 411, the switch drive circuit 421, the switch circuit 422, and the insulation circuit 430. Therefore, this figure depicts differences from the comparative example (FIG. 10), and omits depiction of common parts.

Referring to this figure, the pulse generation circuit 411 includes drivers 411a and 411b and a controller 411c.

An input terminal of the driver 411a is connected to a first output terminal of the controller 411c, that is, a terminal to which a drive pulse Pa is applied. An output terminal of the driver 411a is connected to a first terminal of an insulation capacitor Cia. The driver 411a drives the insulation capacitor Cia in response to the drive pulse Pa. For example, when the drive pulse Pa is at a high level, the driver 411a sources a current from the terminal, to which the power supply voltage VCC is applied, to the insulation capacitor Cia. On the other hand, when the drive pulse Pa is at a low level, the driver 411a sinks a current from the insulation capacitor Cia to the terminal to which the ground voltage GND is applied.

An input terminal of the driver 411b is connected to a second output terminal of the controller 411c, that is, a terminal to which a drive pulse Pb is applied. An output terminal of the driver 411b is connected to a first terminal of an insulation capacitor Cib. The driver 411b drives the insulation capacitor Cib in response to the drive pulse Pb. For example, when the drive pulse Pb is at a high level, the driver 411b sources a current from the terminal, to which the power supply voltage VCC is applied, to the insulation capacitor Cib. On the other hand, when the drive pulse Pb is at a low level, the driver 411b sinks a current from the terminal, to which the ground voltage GND is applied, to the insulation capacitor Cib.

The controller 411c generates the drive pulses Pa and Pb in different phases. That is, when the drive pulse Pa is at a high level (for example, the power supply voltage VCC or lower), the drive pulse Pb is at a low level (for example, the ground voltage GND). When the drive pulse Pa is at a low level, the drive pulse Pb is at a high level.

The switch drive circuit 421 rectifies and smoothes the drive pulses Ia and Ib transmitted via the insulation capacitors Cia and Cib to generate a switch drive signal Vg. Referring to the figure, the switch drive circuit 421 includes diodes D1 to D8, capacitors C1, C2, and Co, and a discharge circuit 421X.

A cathode of the diode D1 and an anode of the diode D2 are connected to the second terminal of the insulation capacitor Cia. An anode of the diode D1 is connected to the reference node nd. A cathode of the diode D2 is connected to the application terminal for the node voltage Va. The diodes D1 and D2 form a rectifier circuit 421a that generates the node voltage Va from the drive pulse Ia transmitted via the insulation capacitor Cia. The diode D1 corresponds to a first rectifier element connected between the insulation capacitor Cia and the reference node nd. The diode D2 corresponds to a second rectifier element connected between the insulation capacitor Cia and the application terminal for the node voltage Va.

A cathode of the diode D3 and an anode of the diode D4 are connected to the second terminal of the insulation capacitor Cib. An anode of the diode D3 is connected to the reference node nd. A cathode of the diode D4 is connected to the application terminal for the node voltage Va. The diodes D3 and D4 form a rectifier circuit 421b that generates the node voltage Va from the drive pulse Ib transmitted via the insulation capacitor Cib. The diode D3 corresponds to a third rectifier element connected between the insulation capacitor Cib and the reference node nd. The diode D4 corresponds to a fourth rectifier element connected between the insulation capacitor Cib and the application terminal for the node voltage Va.

A cathode of the diode D5 and an anode of the diode D6 are connected to a first terminal of the capacitor C1. A second terminal of the capacitor C1 is connected to the second terminal of the insulation capacitor Cia. An anode of the diode D5 is connected to the application terminal for node voltage Va. A cathode of the diode D6 is connected to the application terminal for the switch drive signal Vg. The diodes D5 and D6 and the capacitor C1 form a rectifier circuit 421c that generates the switch drive signal Vg from the drive pulse Ia transmitted via the insulation capacitor Cia. The diode D5 corresponds to a fifth rectifier element connected between the insulation capacitor Cia and the application terminal for the node voltage Va. The diode D6 corresponds to a sixth rectifier element connected between the insulation capacitor Cia and the application terminal for the switch drive signal Vg. The capacitor C1 functions as a first capacitor for DC blocking connected between the insulation capacitor Cia and the diodes D5 and D6.

A cathode of the diode D7 and an anode of the diode D8 are connected to a first terminal of the capacitor C2. A second terminal of the capacitor C2 is connected to the second terminal of the insulation capacitor Cib. An anode of the diode D7 is connected to the application terminal for the node voltage Va. A cathode of the diode D8 is connected to the application terminal for the switch drive signal Vg. The diodes D7 and D8 and the capacitor C2 form a rectifier circuit 421d that generates the switch drive signal Vg from the drive pulse Ib transmitted via the insulation capacitor Cib. The diode D7 corresponds to a seventh rectifier element connected between the insulation capacitor Cib and the application terminal for the node voltage Va. The diode D8 corresponds to an eighth rectifier element connected between the insulation capacitor Cib and the application terminal for the switch drive signal Vg. The capacitor C2 functions as a second capacitor for DC blocking connected between the insulation capacitor Cib and the diodes D7 and D8.

As described above, in the insulated switch 400 of this embodiment, the rectifier circuits 421c and 421d are connected in cascade to the output terminals of the rectifier circuits 421a and 421b, that is, the terminals to which the node voltage Va is applied. Therefore, the switch drive circuit 421 obtains the switch drive signal Vg higher than the node voltage Va. Accordingly, even if the transistor M0 is a GaN device or a SiC device, it may be reliably turned on.

The capacitor Co is connected between the application terminal for the node voltage Va and the reference node nd. The reference node nd is connected to the external terminal T5. The capacitor Co functions as an output capacitor that smoothes the node voltage Va.

The discharge circuit 421X is connected between the application terminal for the switch drive signal Vg and the application terminal for the ground voltage PGND, as in the comparative example (FIG. 10) described above.

The switch circuit 422 includes a transistor M0 instead of the aforementioned transistors M0a and M0b. The transistor M0 may be of, for example, an N-channel type. A drain of the transistor M0 is connected to the external terminal T4. A source of the transistor M0 is connected to the external terminal T5. A gate of the transistor M0 is connected to the application terminal for the switch drive signal Vg. In this way, the output transistor forming the switch circuit 422 may be a single element.

The insulation capacitor Cia insulates the pulse generating circuit 411 and the switch drive circuit 421 from each other, and transmits the drive pulse Pa generated by the pulse generation circuit 411 to the switch drive circuit 421 as a drive pulse Ia.

The insulation capacitor Cib insulates the pulse generation circuit 411 and the switch drive circuit 421 from each other, and transmits the drive pulse Pb generated by the pulse generation circuit 411 to the switch drive circuit 421 as a drive pulse Ib.

The drive pulses Ia and Ib, which are current signals, have current directions that are frequently switched between a positive direction and a negative direction. The positive direction may be defined as a direction extending from the primary-side circuit system 400p to the secondary circuit system 400s via the insulation capacitors Cia and Cib. On the other hand, the negative direction may be defined as a direction extending from the secondary circuit system 400s to the primary-side circuit system 400p via the insulation capacitors Cia and Cib.

However, as mentioned above, the drive pulses Ia and Ib are driven in different phases. That is, when the drive pulse Ia flows in the positive direction, the drive pulse Ib flows in the negative direction. Conversely, when the drive pulse Ia flows in the negative direction, the drive pulse Ib flows in the positive direction. Therefore, the sum of the currents of the drive pulses Ia and Ib is ideally always zero. Accordingly, fluctuations in the current flowing through the capacitor C0 are suppressed, which makes it possible to reduce radiation noise.

### Insulated Switch (Second Embodiment)

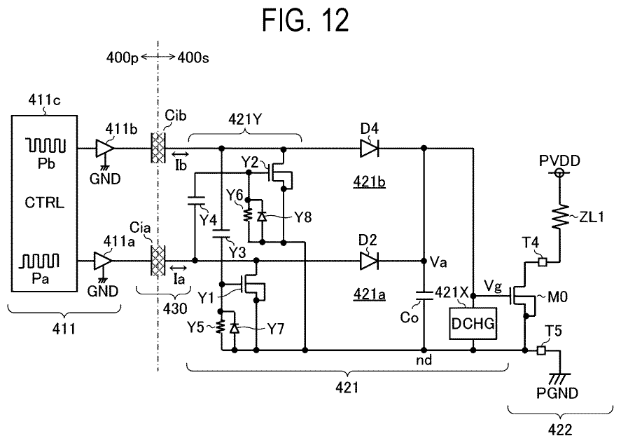

FIG. 12 shows a second embodiment of the insulated switch 400. In this embodiment, the switch drive circuit 421 is based on the first embodiment (FIG. 11) and includes a clamp circuit 421Y.

In this figure, in order to focus on the clamp circuit 421Y, the rectifier circuits 421c and 421d, which are not essential for introducing the clamp circuit 421Y, are omitted. That is, the cathodes of the diodes D2 and D4 are connected to the application terminal for the switch drive signal Vg. Accordingly, the aforementioned node voltage Va corresponds to the switch drive signal Vg.

The clamp circuit 421Y limits the voltages generated at the application terminals of the drive pulses Ia and Ib. The clamp circuit 421Y may be understood as one of CMTI (common mode transient immunity) countermeasure circuits.

Referring to this figure, the clamp circuit 421Y includes transistors Y1 and Y2, capacitors Y3 and Y4, resistors Y5 and Y6, and diodes Y7 and Y8.

A drain of the transistor Y1 is connected to the second terminal of the insulation capacitor Cia. A source of the transistor Y1 is connected to the reference node nd. The capacitor Y3 is connected between a gate of the transistor Y1 and the second terminal of the insulation capacitor Cib. The resistor Y5 and the diode Y7 are connected in parallel between the gate of the transistor Y1 and the reference node nd. The transistor Y1 connected in this manner functions as a first discharge element that electrically connects and disconnects the application terminal for the drive pulse Ia and the reference node nd in response to the drive pulse Ib. The transistor Y1 functions in the same manner as the diode D1 mentioned above. However, when a surge occurs in the ground voltage GND, a parasitic diode associated with the transistor Y1 functions in the same manner as the diode D1.

A drain of the transistor Y2 is connected to the second terminal of the insulation capacitor Cib. A source of the transistor Y2 is connected to the reference node nd. The capacitor Y4 is connected between a gate of the transistor Y2 and the second terminal of the insulation capacitor Cia. The resistor Y6 and the diode Y8 are connected in parallel between the gate of the transistor Y2 and the reference node nd. The transistor Y2 connected in this manner functions as a second discharge element that electrically connects and disconnects the application terminal for the drive pulse Ib and the reference node nd in response to the drive pulse Ia. The transistor Y2 functions in the same manner as the diode D3 mentioned above. However, when a surge occurs in the ground voltage GND, a parasitic diode associated with the transistor Y2 functions in the same manner as the diode D3.

When a positive surge is superimposed on the ground voltage GND of the primary-side circuit system 400p, the voltage applied to the first terminal of each of the insulation capacitors Cia and Cib jumps up relative to the ground voltage PGND of the secondary circuit system 400s. Accordingly, due to the capacitive coupling of each of the insulation capacitors Cia and Cib, the voltage applied to the second terminal of each of the insulation capacitors Cia and Cib also jumps up.

In a case in which the clamp circuit 421Y is not provided, an excessive current flows from the second terminals of the insulation capacitors Cia and Cib to the gate of the transistor M0. As a result, the transistor M0 may be unintentionally turned on.

On the other hand, in a case in which the clamp circuit 421Y is introduced, as the voltage applied to the second terminal of each of the insulation capacitors Cia and Cib increases, the voltage applied to the gate of each of the transistors Y1 and Y2 also increases. Accordingly, both of the transistors Y1 and Y2 are turned on. At this time, a current flows from the second terminal of each of the insulation capacitors Cia and Cib to the reference node nd via the transistors Y1 and Y2. As a result, the increase in the voltage applied to the second terminal of each of the insulation capacitors Cia and Cib may be suppressed.

Further, when a negative surge is superimposed on the ground voltage GND of the primary-side circuit system 400p, the voltages applied to the second terminals of the insulation capacitors Cia and Cib may be clamped by the diodes D1 and D2 that are in a forward bias state.

### Insulated Switch (Third Embodiment)

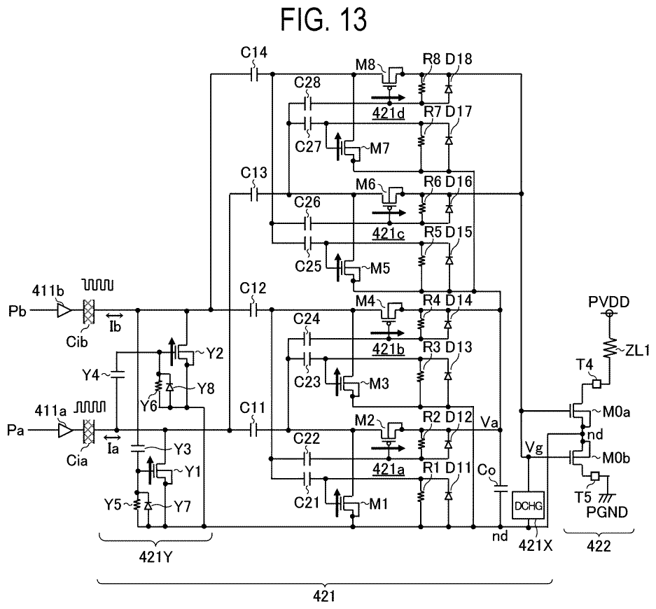

FIG. 13 shows a third embodiment of the insulated switch 400. In this embodiment, the switch drive circuit 421 is based on the first embodiment (FIG. 11) and includes the clamp circuit 421Y of the second embodiment (FIG. 12). The switch circuit 422 includes transistors M0a and M0b as output transistors, as in the comparative example (FIG. 10). Further, the switch drive circuit 421 also includes modifications to the configuration of each of the rectifier circuits 421a, 421b, 421c, and 421d.

Referring to this figure, the switch drive circuit 421 includes transistors M1 to M8, capacitors C11 to C14 and C21 to C28, resistors R1 to R8, and diodes D11 to D18 instead of the aforementioned diodes D1 to D8 and capacitors C1 and C2. The transistors M1, M3, M5, and M7 may be of, for example, N-channel types. The transistors M2, M4, M6, and M8 may be of, for example, P-channel types.

Drains of the transistors M1 and M2 are connected to a first terminal of the capacitor C11. A second terminal of the capacitor C11 is connected to the second terminal of the insulation capacitor Cia. A source of the transistor M1 is connected to the reference node nd. A source of the transistor M2 is connected to the application terminal for the node voltage Va. The transistors M1 and M2 form a rectifier circuit 421a that generates the node voltage Va from the drive pulse Ia transmitted via the insulation capacitor Cia. The transistor M1 corresponds to a first rectifier element connected between the insulation capacitor Cia and the reference node nd. The transistor M2 corresponds to a second rectifier element connected between the insulation capacitor Cia and the application terminal for the node voltage Va. The capacitor C11 may be omitted.

Drains of the transistors M3 and M4 are connected to a first terminal of the capacitor C12. A second terminal of the capacitor C12 is connected to the second terminal of the insulation capacitor Cib. A source of the transistor M3 is connected to the reference node nd. A source of the transistor M4 is connected to the application terminal for the node voltage Va. The transistors M3 and M4 form a rectifier circuit 421b that generates the node voltage Va from the drive pulse Ib transmitted via the insulation capacitor Cib. The transistor M3 corresponds to a third rectifier element connected between the insulation capacitor Cib and the reference node nd. The transistor M4 corresponds to a fourth rectifier element connected between the insulation capacitor Cib and the application terminal for the node voltage Va. The capacitor C12 may be omitted.

Drains of the transistors M5 and M6 are connected to a first terminal of the capacitor C13. A second terminal of the capacitor C13 is connected to the second terminal of the insulation capacitor Cia. A source of the transistor M5 is connected to the application terminal for the node voltage Va. A source of the transistor M6 is connected to the application end of the switch drive signal Vg. The transistors M5 and M6 and the capacitor C13 form a rectifier circuit 421c that generates the switch drive signal Vg from the drive pulse Ia transmitted via the insulation capacitor Cia. The transistor M5 corresponds to a fifth rectifier element connected between the application terminal for the node voltage Va and the insulation capacitor Cia. The transistor M6 corresponds to a sixth rectifier element connected between the insulation capacitor Cia and the application terminal for the switch drive signal Vg. The capacitor C13 functions as a first capacitor for DC blocking connected between the insulation capacitor Cia and the transistors M5 and M6.

Drains of the transistors M7 and M8 are connected to a first terminal of the capacitor C14. A second terminal of the capacitor C14 is connected to a second terminal of the insulation capacitor Cib. A source of the transistor M7 is connected to the application terminal for the node voltage Va. A source of the transistor M8 is connected to the application terminal for the switch drive signal Vg. The transistors M7 and M8 and the capacitor C14 form a rectifier circuit 421d that generates the switch drive signal Vg from the drive pulse Ib transmitted via the insulation capacitor Cib. The transistor M7 corresponds to a seventh rectifier element connected between the insulation capacitor Cib and the application terminal for the node voltage Va. The transistor M8 corresponds to an eighth rectifier element connected between the insulation capacitor Cib and the application terminal for the switch drive signal Vg. The capacitor C14 functions as a second capacitor for DC blocking connected between the insulation capacitor Cib and the transistors M7 and M7.

As described above, in the insulated switch 400 of this embodiment, the rectifier circuits 421c and 421d are connected in cascade to the output terminals of the rectifier circuits 421a and 421b, that is, the application terminals for the node voltage Va. Therefore, the switch drive circuit 421 obtains the switch drive signal Vg higher than the node voltage Va. Accordingly, even if the transistor M0 is a GaN device or a SiC device, it may be reliably turned on.

In particular, the drain-source voltages Vds(M1) to Vds(M8) of the transistors M1 to M8 when they are turned on are lower than the forward drop voltages Vf(D1) to Vf(D8) of the diodes D1 to D8 in the first embodiment (FIG. 11), respectively. Accordingly, in this embodiment, the voltage loss in the switch drive circuit 421 may be reduced compared to the first embodiment (FIG. 11).

The capacitor C21 is connected between the gate of the transistor M1 and the capacitor C12, and further between the gate of the transistor M1 and the insulation capacitor Cib. The capacitor C22 is connected between the gate of the transistor M2 and the capacitor C12, and further between the gate of the transistor M2 and the insulation capacitor Cib.

The capacitor C23 is connected between the gate of the transistor M3 and the capacitor C11, and further between the gate of the transistor M3 and the insulation capacitor Cia. The capacitor C24 is connected between the gate of the transistor M4 and the capacitor C11, and further between the gate of the transistor M4 and the insulation capacitor Cia.

The capacitor C25 is connected between the gate of the transistor M5 and the capacitor C14, and further between the gate of the transistor M5 and the insulation capacitor Cib. The capacitor C26 is connected between the gate of the transistor M6 and the capacitor C14, and further between the gate of the transistor M6 and the insulation capacitor Cib.

The capacitor C27 is connected between the gate of the transistor M7 and the capacitor C13, and further between the gate of the transistor M7 and the insulation capacitor Cia. The capacitor C28 is connected between the gate of the transistor M8 and the capacitor C13, and further between the gate of the transistor M8 and the insulation capacitor Cia.

The resistors R1 to R8 are connected between the gates and sources of the transistors M1 to M8, respectively. That is, the voltages across the resistors R1 to R8 correspond to the gate-source voltages Vgs(M1) to Vgs(M8) of the transistors M1 to M8, respectively.

A cathode of the diode D11 is connected to the gate of the transistor M1. An anode of the diode D11 is connected to the source of the transistor M1. An anode of the diode D12 is connected to the gate of the transistor M2. A cathode of the diode D12 is connected to the source of the transistor M2.

A cathode of the diode D13 is connected to the gate of the transistor M3. An anode of the diode D13 is connected to the source of the transistor M3. An anode of the diode D14 is connected to the gate of the transistor M4. A cathode of the diode D14 is connected to the source of the transistor M4.

A cathode of the diode D15 is connected to the gate of the transistor M5. An anode of the diode D15 is connected to the source of the transistor M5. An anode of the diode D16 is connected to the gate of the transistor M6. A cathode of the diode D16 is connected to the source of the transistor M6.

A cathode of the diode D17 is connected to the gate of the transistor M7. An anode of the diode D17 is connected to the source of the transistor M7. An anode of the diode D18 is connected to the gate of the transistor M8. A cathode of the diode D18 is connected to the source of the transistor M8.

The transistors M1, M2, M5, and M6 are driven in response to the drive pulse Ib. When the drive pulse Ib is being driven in a pulse manner, the gate voltages of the transistors M1, M2, M5, and M6 rise. Therefore, the transistors M1 and M5 are turned on, and the transistors M2 and M6 are turned off. On the other hand, when the pulse drive of the drive pulse Ib is stopped, the gate voltages of the transistors M1, M2, M5, and M6 fall. Therefore, the transistors M1 and M5 are turned off, and the transistors M2 and M6 are turned on.

The transistors M3, M4, M7, and M8 are driven in response to the drive pulse Ia. When the drive pulse Ia is being driven in a pulse manner, the gate voltages of the transistors M3, M4, M7, and M8 rise. Therefore, the transistors M3 and M7 are turned on, and the transistors M4 and M8 are turned off. On the other hand, when the pulse drive of the drive pulse Ia is stopped, the gate voltages of the transistors M3, M4, M7, and M8 fall. Therefore, the transistors M3 and M7 are turned off, and the transistors M4 and M8 are turned on.

With this configuration, it is not necessary to provide separate control signals for each of the transistors M1 to M8. When it is necessary to reduce the on-resistance of each of the transistors M1 to M8, the diodes D11 to D18 may be connected in parallel to the resistors R1 to R8, respectively, in order to increase the gate-source voltage Vgs of each of the transistors M1 to M8.

### Discharge Circuit (First Example)

FIG. 14 shows a first example of the discharge circuit 421X. The discharge circuit 421X of the first example includes a resistor X1.

The resistor X1 may be understood as a discharge resistor connected between the application terminal for the switch drive signal Vg and the reference node nd. The discharge circuit 421X of the first example may discharge the switch drive signal Vg with an extremely simple circuit configuration.

### Discharge Circuit (Second Example)

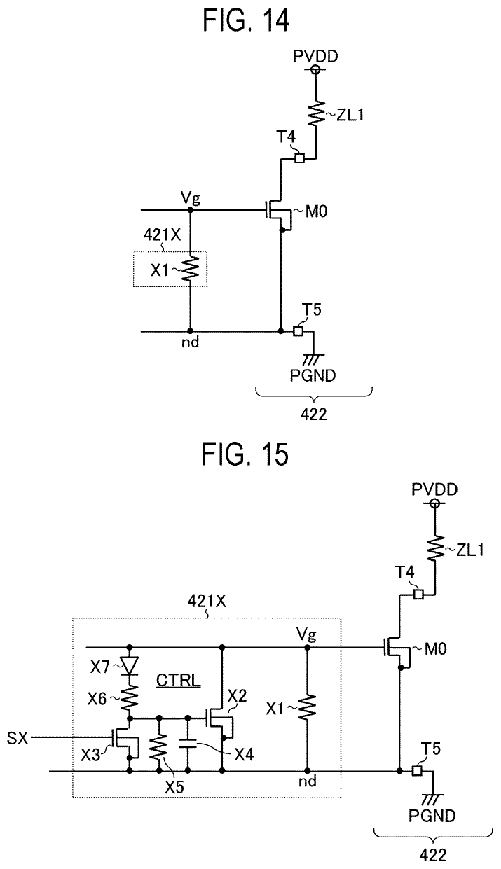

FIG. 15 shows a second example of the discharge circuit 421X. The second example of the discharge circuit 421X is based on the first example (FIG. 14) and further includes transistors X2 and X3, a capacitor X4, resistors X5 and X6, and a diode X7. The transistors X2 and X3 may be, for example, N-channel transistors.

A drain of the transistor X2 is connected to the application terminal for the switch drive signal Vg. A source of the transistor X2 is connected to the reference node nd. The transistor X2 functions as a low-impedance discharge switch connected between the application terminal for the switch drive signal Vg and the reference node nd.

An anode of the diode X7 is connected to the application terminal for the switch drive signal Vg. A cathode of the diode X7 is connected to the first terminal of the resistor X6. A second terminal of the resistor X6, a drain of the transistor X3, and first terminals of the capacitor X4 and the resistor X5 are connected to a gate of the transistor X2. A source of the transistor X3, and second terminals of the capacitor X4 and the resistor X5 are connected to the reference node nd. A gate of the transistor X3 is connected to the application terminal for the control signal SX.

The application terminal for the control signal SX may be connected to the node that is driven in a pulse manner when the switch drive signal Vg is set to a high level, for example, the gate of the transistor M1 or M3 in the third embodiment (FIG. 13).

When the control signal SX is driven in a pulse manner, the transistor X2 is turned off, and therefore the discharge path via the transistor X2 is disconnected. On the other hand, when the control signal SX is not driven in a pulse manner, the transistor X2 is turned on, and therefore the discharge path via the transistor X2 is electrically connected.

In this way, the transistor X3, the capacitor X4, the resistors X5 and X6, and the diode X7 form a controller CTRL that drives the transistor X2 in response to the control signal SX. As shown in this figure, the controller CTRL may operate using the switch drive signal Vg as a power source.

The discharge circuit 421X of the second example may discharge the switch drive signal Vg faster than the first example (FIG. 14), thereby enabling high-speed switching of the transistor M0 or the transistors M0a and M0b.

The discharge circuit 421X of the second example may not be based on the first example (FIG. 14). That is, the resistor X1 may be omitted.

### Insulated Switch (Fourth Embodiment)

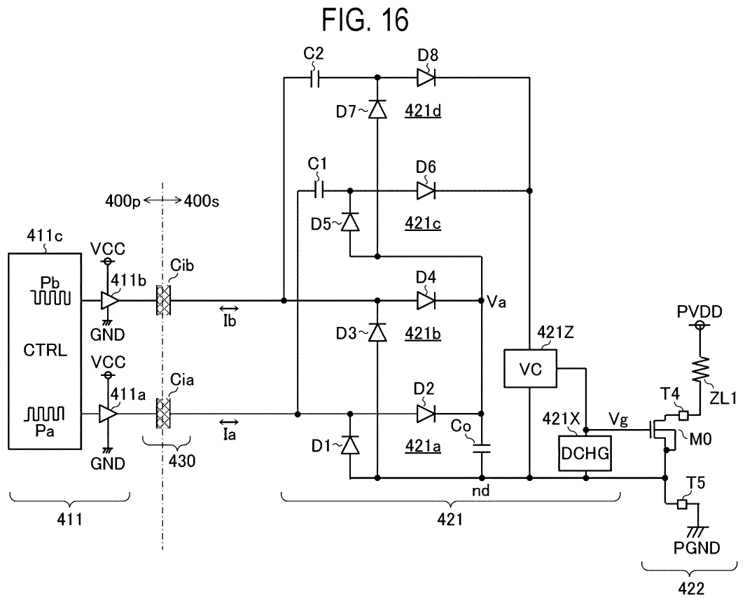

FIG. 16 shows a fourth embodiment of the insulated switch 400. The insulated switch 400 of this embodiment is based on the first embodiment (FIG. 11) and further includes a voltage-controlled circuit 421Z as a component of the switch drive circuit 421.

When a GaN device or the like is used as the transistor M0, a switch drive signal Vg with a certain degree of precision is required. For example, the switch drive signal Vg may require an output precision of 5 V±10%. However, the rectifier circuits 421a to 421d, which are composed of the diodes D1 to D8 and the capacitors C1, C2, and Co, may not necessarily be able to provide such output precision.

Therefore, the insulated switch 400 of this embodiment includes a voltage-controlled circuit 421Z as a component of the switch drive circuit 421. The voltage-controlled circuit 421Z may be provided, for example, between the rectifier circuits 421c and 421d and the application terminal for the switch drive signal Vg. The voltage-controlled circuit 421Z stabilizes the switch drive signal Vg and outputs the same to the gate of the transistor M0. With this configuration, the transistor M0 may be appropriately driven.

### Voltage-Controlled Circuit

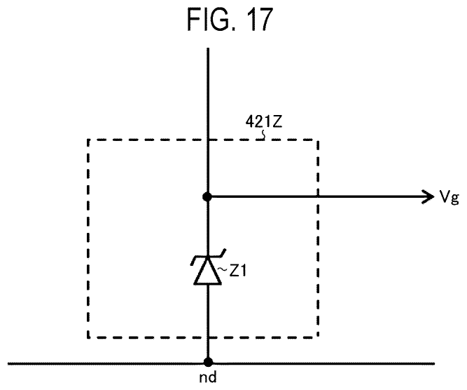

FIG. 17 is a diagram showing one configuration example of the voltage-controlled circuit 421Z. The voltage-controlled circuit 421Z of this configuration example includes a Zener diode Z1. A cathode of the Zener diode Z1 is connected to the application terminal for the switch drive signal Vg. An anode of the Zener diode Z1 is connected to a common node nd and further to the external terminal T5. The common node nd and the external terminal T5 may be understood as examples of a reference potential terminal. With this configuration, the voltage-controlled circuit 421Z may be easily implemented.

### Combination of Embodiments

The various embodiments described above may be combined with each other with the scope that does not cause contradiction. For example, the discharge circuits 421X of the first example (FIG. 14) and the second example (FIG. 15) may be applied to any of the first embodiment (FIG. 11), the second embodiment (FIG. 12), and the third embodiment (FIG. 13). Further, the aforementioned voltage-controlled circuit 421Z may be incorporated into any of the second embodiment (FIG. 12) and the third embodiment (FIG. 13).

### Supplementary Notes

According to the present disclosure, the high level of the switch drive signal can be raised. Hereinafter, some aspects of the present disclosure will be additionally described as supplementary notes.

### Supplementary Note 1

An insulated switch 400, comprising:
a switch circuit 422 connected between a first node T4 and a second node T5 and configured to be turned on and off by a switch drive signal Vg;
a pulse generation circuit 411 configured to generate a first drive pulse Pa and a second drive pulse Pb in different phases;
a switch drive circuit 421 configured to receive a third drive pulse Ia and a fourth drive pulse Ib to generate the switch drive signal Vg; and
a first insulation capacitor Cia and a second insulation capacitor Cib configured to transmit the first drive pulse Pa and the second drive pulse Pb as the third drive pulse Ia and the fourth drive pulse Ib, respectively, while insulating the pulse generation circuit 411 and the switch drive circuit 421 from each other.

### Supplementary Note 2

In the insulated switch 400 of Supplementary Note 1 above, the switch circuit 422 includes at least one output transistor M0, M0a or M0b having a gate connected to an application terminal for the switch drive signal Vg.

### Supplementary Note 3

In the insulated switch 400 of Supplementary Note 2 above, the output transistor M0, M0a or M0b is a GaN device or a SiC device.

### Supplementary Note 4

In the insulated switch 400 of any one of Supplementary Notes 1 to 3 above,
the switch drive circuit 421 includes:
a first rectifier circuit 421a and a second rectifier circuit 421b configured to generate a node voltage Va from the third drive pulse Ia and the fourth drive pulse Ib; and
a third rectifier circuit 421c and a fourth rectifier circuit 421d connected in cascade to output terminals of the first rectifier circuit 421a and the second rectifier circuit 421b, respectively, and configured to generate the switch drive signal Vg higher than the node voltage Va from the third drive pulse Ia and the fourth drive pulse Ib.

### Supplementary Note 5

In the insulated switch 400 of Supplementary Note 4 above, the first rectifier circuit 421a includes a first rectifier element D1 or M1 configured to be connected between the first insulation capacitor Cia and a reference node nd, and a second rectifier element D2 or M2 configured to be connected between the first insulation capacitor Cia and an application terminal for the node voltage Va,
the second rectifier circuit 421b includes a third rectifier element D3 or M3 configured to be connected between the second insulation capacitor Cib and the reference node nd, and a fourth rectifier element D4 or M4 configured to be connected between the second insulation capacitor Cib and the application terminal for the node voltage Va,
the third rectifier circuit 421c includes a fifth rectifier element D5 or M5 configured to be connected between the first insulation capacitor Cia and the application terminal for the node voltage Va, a sixth rectifier element D6 or M6 configured to be connected between the first insulation capacitor Cia and the application terminal for the switch drive signal Vg, and a first capacitor C1 or C13 configured to be connected between the second insulation capacitor Cib and the fifth rectifier element D5 or M5 and the sixth rectifier element D6 or M6, and
the fourth rectifier circuit 421d includes a seventh rectifier element D7 or M7 configured to be connected between the second insulation capacitor Cib and the application terminal for the node voltage Va, an eighth rectifier element D8 or M8 configured to be connected between the second insulation capacitor Cib and the application terminal for the switch drive signal Vg, and a second capacitor C2 or C14 configured to be connected between the second insulation capacitor Cib and the seventh rectifier element D7 or M7 and the eighth rectifier element D8 or M8.

### Supplementary Note 6

In the insulated switch 400 of Supplementary Note 5 above, the first rectifier element D1, the second rectifier element D2, the third rectifier element D3, the fourth rectifier element D4, the fifth rectifier element D5, the sixth rectifier element D6, the seventh rectifier element D7, and the eighth rectifier element D8 are all diodes.

### Supplementary Note 7

In the insulated switch 400 of Supplementary Note 5 above, the first rectifier element M1, the second rectifier element M2, the third rectifier element M3, the fourth rectifier element M4, the fifth rectifier element M5, the sixth rectifier element M6, the seventh rectifier element M7, and the eighth rectifier element M8 are all transistors.

### Supplementary Note 8

In the insulated switch 400 of Supplementary Note 7 above, the first rectifier element M1, the second rectifier element M2, the fifth rectifier element M5, and the sixth rectifier element M6 are driven in response to the fourth drive pulse Ib, and the third rectifier element M3, the fourth rectifier element M4, the seventh rectifier element M7, and the eighth rectifier element M8 are driven in response to the third drive pulse Ia.

### Supplementary Note 9

In the insulated switch 400 of any one of Supplementary Notes 1 to 8 above, the switch drive circuit 421 further includes a clamp circuit 421Y configured to limit the voltage generated at an application terminal for each of the third drive pulse Ia and the fourth drive pulse Ib.

### Supplementary Note 10

In the insulated switch 400 of Supplementary Note 9 above, the clamp circuit 421Y includes a first discharge element Y1 configured to electrically connect and disconnect the application terminal for the third drive pulse Ia and the reference node nd in response to the fourth drive pulse Ib, and a second discharge element Y2 configured to electrically connect and disconnect the application terminal for the fourth drive pulse Ib and the reference node nd in response to the third drive pulse Ia.

### Supplementary Note 11

In the insulated switch 400 of any one of Supplementary Notes 1 to 10 above, the switch drive circuit 421 further includes a discharge circuit 421X configured to discharge the switch drive signal Vg.

### Supplementary Note 12

In the insulated switch 400 of Supplementary Note 11 above, the discharge circuit 421X includes a discharge resistor X1 configured to be connected between the application terminal for the switch drive signal Vg and the reference node nd.

### Supplementary Note 13

In the insulated switch 400 of Supplementary Note 11 or 12 above, the discharge circuit 421X includes a discharge switch X2 configured to be connected between the application terminal for the switch drive signal Vg and the reference node nd, and a controller CTRL configured to drive the discharge switch X2 in response to a control signal SX.

### Supplementary Note 14

In the insulated switch 400 of Supplementary Note 13 above, the controller CTRL operates using the switch drive signal Vg as a power source.

### Supplementary Note 15

In the insulated switch 400 of any one of Supplementary Notes 1 to 14 above, the switch drive circuit 421 includes a voltage-controlled circuit 421Z configured to stabilize the switch drive signal Vg.

### Supplementary Note 16

In the insulated switch 400 of Supplementary Note 15 above, the voltage-controlled circuit 421Z includes a Zener diode Z1 configured to be connected between the application terminal for the switch drive signal Vg and a reference potential terminal T5 or nd.

### Supplementary Note 17

An electronic device A, comprising: the insulated switch 400 of any one of Supplementary Notes 1 to 16 above.

### Others

In addition to the above-described embodiments, the various technical features disclosed in this specification may be modified in various ways without departing from the spirit of the technical creation. In other words, the above-described embodiments should be considered to be exemplary and not limitative in all respects. Further, the technical scope of the present disclosure is defined by the claims, and should be understood to include all modifications that fall within the meaning and scope of the claims.

What is claimed is:

1. An insulated switch, comprising:
a switch circuit connected between a first node and a second node and configured to be turned on and off by a switch drive signal;
a pulse generation circuit configured to generate a first drive pulse and a second drive pulse in different phases;
a switch drive circuit configured to receive a third drive pulse and a fourth drive pulse to generate the switch drive signal; and
a first insulation capacitor and a second insulation capacitor configured to transmit the first drive pulse and the second drive pulse as the third drive pulse and the fourth drive pulse, respectively, while insulating the pulse generation circuit and the switch drive circuit from each other.

2. The insulated switch of claim 1, wherein the switch circuit includes at least one output transistor having a gate connected to an application terminal for the switch drive signal.

3. The insulated switch of claim 2, wherein the output transistor is a GaN device or a SiC device.

4. The insulated switch of claim 1, wherein the switch drive circuit includes:
a first rectifier circuit and a second rectifier circuit configured to generate a node voltage from the third drive pulse and the fourth drive pulse; and
a third rectifier circuit and a fourth rectifier circuit connected in cascade to output terminals of the first rectifier circuit and the second rectifier circuit, respectively, and configured to generate the switch drive signal higher than the node voltage from the third drive pulse and the fourth drive pulse.

5. The insulated switch of claim 4, wherein the first rectifier circuit includes a first rectifier element configured to be connected between the first insulation capacitor and a reference node, and a second rectifier element configured to be connected between the first insulation capacitor and an application terminal for the node voltage,
wherein the second rectifier circuit includes a third rectifier element configured to be connected between the second insulation capacitor and the reference node, and a fourth rectifier element configured to be connected between the second insulation capacitor and the application terminal for the node voltage,
wherein the third rectifier circuit includes a fifth rectifier element configured to be connected between the first insulation capacitor and the application terminal for the node voltage, a sixth rectifier element configured to be connected between the first insulation capacitor and the application terminal for the switch drive signal, and a first capacitor configured to be connected between the second insulation capacitor and the fifth rectifier element and the sixth rectifier element, and
wherein the fourth rectifier circuit includes a seventh rectifier element configured to be connected between the second insulation capacitor and the application terminal for the node voltage, an eighth rectifier element configured to be connected between the second insulation capacitor and the application terminal for the switch drive signal, and a second capacitor configured to be connected between the second insulation capacitor and the seventh rectifier element and the eighth rectifier element.

6. The insulated switch of claim 5, wherein the first rectifier element, the second rectifier element, the third rectifier element, the fourth rectifier element, the fifth rectifier element, the sixth rectifier element, the seventh rectifier element, and the eighth rectifier element are all diodes.

7. The insulated switch of claim 5, wherein the first rectifier element, the second rectifier element, the third rectifier element, the fourth rectifier element, the fifth rectifier element, the sixth rectifier element, the seventh rectifier element, and the eighth rectifier element are all transistors.

8. The insulated switch of claim 7, wherein the first rectifier element, the second rectifier element, the fifth rectifier element, and the sixth rectifier element are driven in response to the fourth drive pulse, and the third rectifier element, the fourth rectifier element, the seventh rectifier element, and the eighth rectifier element are driven in response to the third drive pulse.

9. The insulated switch of claim 1, wherein the switch drive circuit further includes a clamp circuit configured to limit a voltage generated at an application terminal for each of the third drive pulse and the fourth drive pulse.

10. The insulated switch of claim 9, wherein the clamp circuit includes a first discharge element configured to electrically connect and disconnect the application terminal for the third drive pulse and the reference node in response to the fourth drive pulse, and a second discharge element configured to electrically connect and disconnect the application terminal for the fourth drive pulse and the reference node in response to the third drive pulse.

11. The insulated switch of claim 1, wherein the switch drive circuit further includes a discharge circuit configured to discharge the switch drive signal.

12. The insulated switch of claim 11, wherein the discharge circuit includes a discharge resistor configured to be connected between the application terminal for the switch drive signal and the reference node.

13. The insulated switch of claim 11, wherein the discharge circuit includes a discharge switch configured to be connected between the application terminal for the switch drive signal and the reference node, and a controller configured to drive the discharge switch in response to a control signal.

14. The insulated switch of claim 13, wherein the controller operates using the switch drive signal as a power source.

15. The insulated switch of claim 1, wherein the switch drive circuit includes a voltage-controlled circuit configured to stabilize the switch drive signal.

16. The insulated switch of claim 15, wherein the voltage-controlled circuit includes a Zener diode configured to be connected between the application terminal for the switch drive signal and a reference potential terminal.

17. An electronic device, comprising: the insulated switch of claim 1.
